(19) United States
(12) Patent Application Publication
(10) Pub. No.: US 2023/0122519 A1
(43) Pub. Date: Apr. 20, 2023

(54) SEMICONDUCTOR DEVICE AND METHOD FOR PRODUCING SAME

(71) Applicant: ROHM CO., LTD., Kyoto-shi, Kyoto (JP)

(72) Inventors: Toshio NAGATA, Kyoto-shi, Kyoto (JP); Kohei SHINSHO, Kyoto-shi, Kyoto (JP)

(73) Assignee: ROHM CO., LTD., Kyoto-shi, Kyoto (JP)

(21) Appl. No.: 17/911,700

(22) PCT Filed: Mar. 23, 2021
(86) PCT No.: PCT/JP2021/012007

§ 371 Date: Sep. 15, 2022

(30) Foreign Application Priority Data
Apr. 22, 2020 (JP) 2020-076315

(51) Int. Cl. C23C 14/14; C23C 14/34; H01L 21/285; H01L 29/786

(52) U.S. Cl. CPC C23C 14/14; C23C 14/34; H01L 21/28518; H01L 29/78603

(57) ABSTRACT

A semiconductor device includes a chip and an electrode that has a laminated structure including a Ti film, a TiN film, a TiAl alloy film and an Al-based metal film that are laminated in that order from the chip side.

### TECHNICAL FIELD

The present application corresponds to Japanese Patent Application No. 2020-076315 filed on Apr. 22, 2020 in the Japan Patent Office, and the entire disclosures of this application are incorporated herein by reference. The present invention relates to a semiconductor device and a method for manufacturing the same.

### BACKGROUND ART

Patent Literature 1 discloses a semiconductor device that includes a semiconductor substrate and an electrode formed on the semiconductor substrate. The electrode has a laminated structure that includes a Ti film, a TiN film and an Al-based metal film that are laminated in that order from the semiconductor substrate side.

### CITATION LIST

### Patent Literature

Patent Literature 1: Japanese Patent Application Publication No. 2000-82742

### SUMMARY OF INVENTION

### Technical Problem

With an electrode that includes a Ti film, a TiN film and an Al-based metal film, there is a problem that a protrusion called whiskers form on an outer surface of the Al-based metal film. Specifically, whiskers are constituted of an Al-based metal crystalline substance that has grown to needle shapes, columnar shapes, linear shapes, rod shapes, etc., from the outer surface of the Al-based metal film. Whiskers increase risk of short circuit failure, film formation failure, appearance defect, etc. As a result of intensive study of whiskers, the present inventors found that the TiN film that becomes a film formation starting point of the Al-based metal film is one factor in the forming of whiskers.

One preferred embodiment of the present invention provides a semiconductor device with which whiskers are suppressed and a method for manufacturing the same.

### Solution to Problem

One preferred embodiment of the present invention provides a semiconductor device including a chip and an electrode that has a laminated structure including a Ti film, a TiN film, a TiAl alloy film and an Al-based metal film that are laminated in that order from the chip side.

One preferred embodiment of the present invention provides a method for manufacturing a semiconductor device including a step of forming a Ti film on a wafer, a step of forming a TiN film on the Ti film, a step of forming a base Ti film on the TiN film, a step of forming a TiAl alloy film by alloying an Al-based metal with the base Ti film by depositing the Al-based metal on the base Ti film by a high-temperature sputtering method, and a step of forming an Al-based metal film by continuing to deposit the Al-based metal on the TiAl alloy film by the high-temperature sputtering method.

The aforementioned as well as yet other objects, features, and effects of the present invention will be made clear by the following description of the preferred embodiments, with reference to the accompanying drawings.

### BRIEF DESCRIPTION OF DRAWINGS

FIG. 1 is a plan view of a semiconductor device according to a first preferred embodiment of the present invention.

FIG. 2 is a sectional view taken along line II-II shown in FIG. 1.

FIG. 3 is a plan view with which a top insulating film has been removed from the structure shown in FIG. 1.

FIG. 4 is an enlarged view of a region IV shown in FIG. 3.

FIG. 5 is a sectional view taken along line V-V shown in FIG. 4.

FIG. 6 is an enlarged view of a region VI shown in FIG. 5.

FIG. 7 is a general sectional view of an outer surface of an Al-based metal film.

FIG. 8A is a sectional view of an example of a method for manufacturing the semiconductor device shown in FIG. 1.

FIG. 8B is a sectional view of a step subsequent to that of FIG. 8A.

FIG. 8C is a sectional view of a step subsequent to that of FIG. 8B.

FIG. 8D is a sectional view of a step subsequent to that of FIG. 8C.

FIG. 8E is a sectional view of a step subsequent to that of FIG. 8D.

FIG. 8F is a sectional view of a step subsequent to that of FIG. 8E.

FIG. 8G is a sectional view of a step subsequent to that of FIG. 8F.

FIG. 8H is a sectional view of a step subsequent to that of FIG. 8G.

FIG. 8I is a sectional view of a step subsequent to that of FIG. 8H.

FIG. 8J is a sectional view of a step subsequent to that of FIG. 8I.

FIG. 8K is a sectional view of a step subsequent to that of FIG. 8J.

FIG. 8L is a sectional view of a step subsequent to that of FIG. 8K.

FIG. 8M is a sectional view of a step subsequent to that of FIG. 8L.

FIG. 8N is a sectional view of a step subsequent to that of FIG. 8M.

FIG. 8O is a sectional view of a step subsequent to that of FIG. 8N.

FIG. 8P is a sectional view of a step subsequent to that of FIG. 8O.

FIG. 8Q is a sectional view of a step subsequent to that of FIG. 8P.

FIG. 8R is a sectional view of a step subsequent to that of FIG. 8Q.

FIG. 8S is a sectional view of a step subsequent to that of FIG. 8R.

FIG. 8T is a sectional view of a step subsequent to that of FIG. 8S.

FIG. 8U is a sectional view of a step subsequent to that of FIG. 8T.

FIG. 8V is a sectional view of a step subsequent to that of FIG. 8U.

FIG. 8W is a sectional view of a step subsequent to that of FIG. 8V.

FIG. 9 is a graph of a relationship of whisker density and temperature.

FIG. 10 is a graph showing in enlarged manner the whisker density at a low temperature side shown in FIG. 9.

FIG. 11 is a sectional view, corresponding to FIG. 5, of a semiconductor device according to a second preferred embodiment of the present invention.

FIG. 12 is a sectional view, corresponding to FIG. 6, of a semiconductor device according to a third preferred embodiment of the present invention.

FIG. 13 is a sectional view, corresponding to FIG. 2, of a semiconductor device according to a fourth preferred embodiment of the present invention.

### DESCRIPTION OF EMBODIMENTS

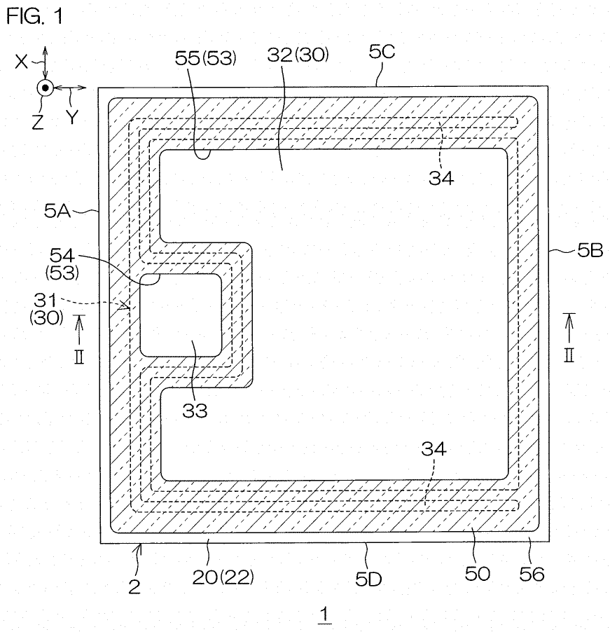

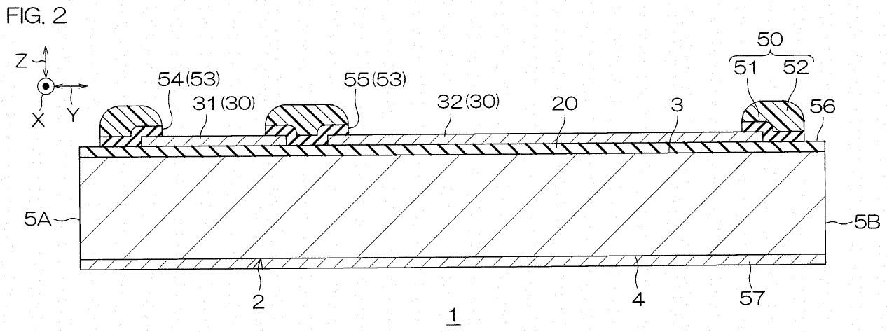

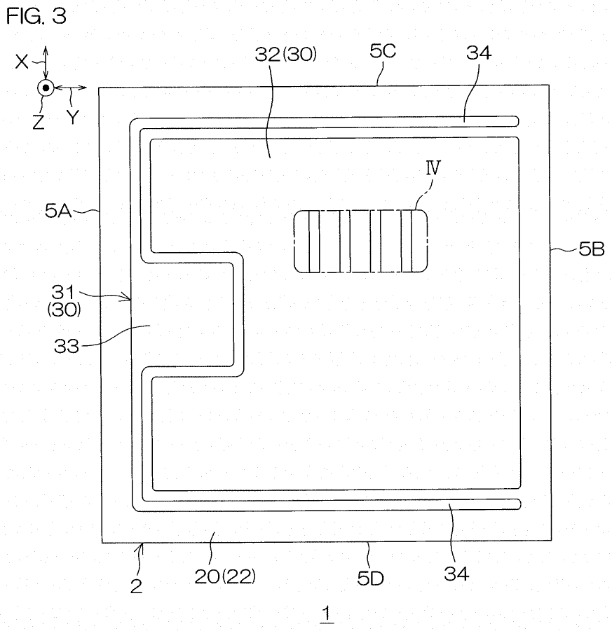

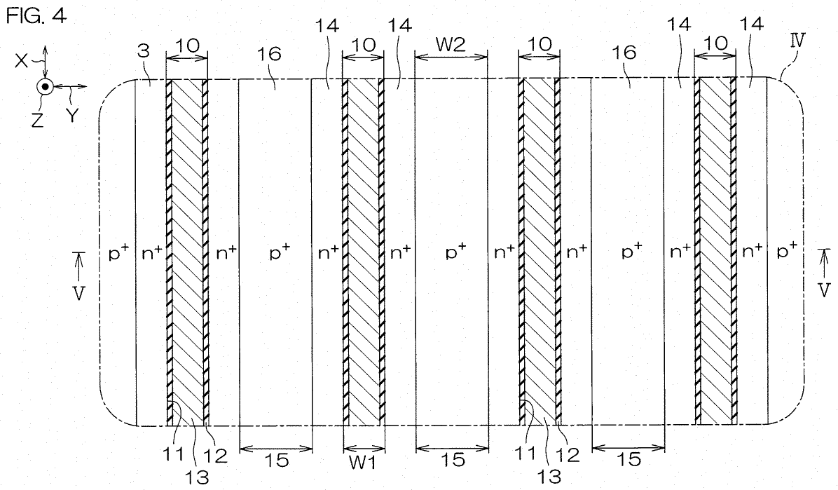

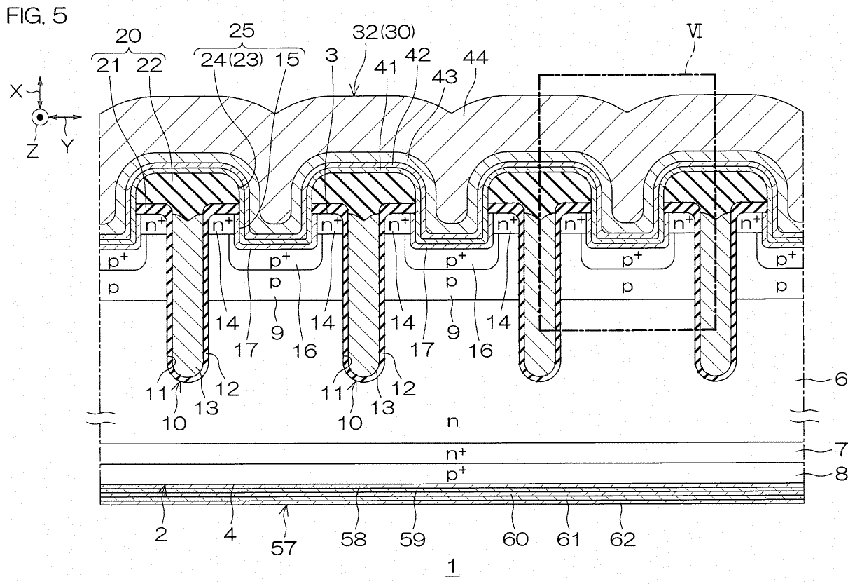

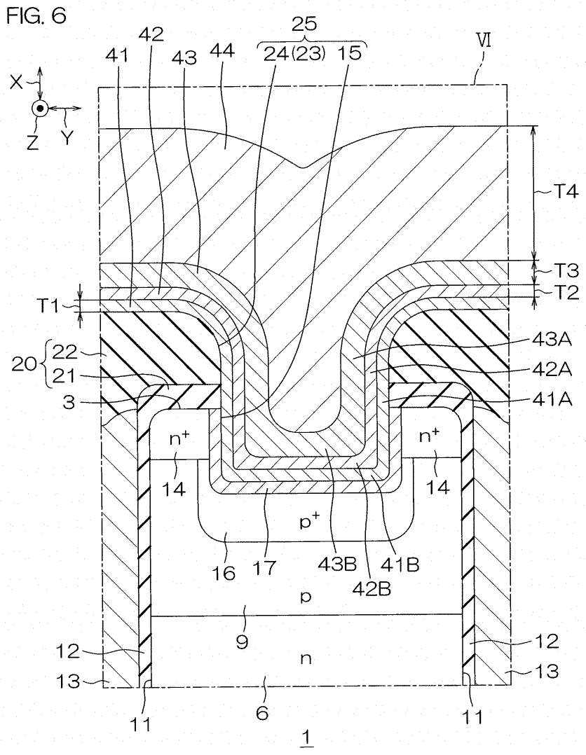

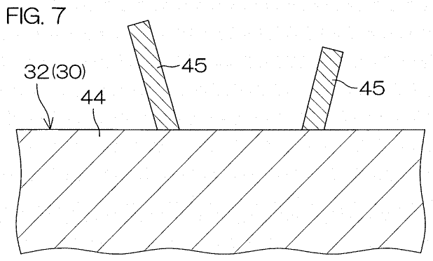

FIG. 1 is a plan view of a semiconductor device 1 according to a first preferred embodiment of the present invention. FIG. 2 is a sectional view taken along line II-II shown in FIG. 1. FIG. 3 is a plan view with which a top insulating film 50 has been removed from the structure shown in FIG. 1. FIG. 4 is an enlarged view of a region IV shown in FIG. 3. FIG. 5 is a sectional view taken along line V-V shown in FIG. 4. FIG. 6 is an enlarged view of a region VI shown in FIG. 5. FIG. 7 is a general sectional view of an outer surface of an Al-based metal film 44.

Referring to FIG. 1 to FIG. 7, in this embodiment, the semiconductor device 1 is constituted of an electronic component (semiconductor switching device) that includes an insulated gate type transistor as an example of a functional device. The functional device includes an IGBT (insulated gate bipolar transistor) in this embodiment. The semiconductor device 1 includes a semiconductor chip 2 (chip) of rectangular parallelepiped shape. The semiconductor chip 2 may be constituted of an Si (silicon) chip or an SiC (silicon carbide) chip. The semiconductor chip 2 is constituted of an Si chip in this embodiment.

The semiconductor chip 2 has a first main surface 3 at one side, a second main surface 4 at another side, and first to fourth side surfaces 5A to 5D that connect the first main surface 3 and the second main surface 4. The first main surface 3 and the second main surface 4 are each formed to a quadrilateral shape in a plan view as viewed from a normal direction Z thereto (hereinafter referred to simply as “plan view”). The first side surface 5A and the second side surface 5B extend in a first direction X and face each other in a second direction Y that is orthogonal to the first direction X. The third side surface 5C and the fourth side surface 5D extend in the second direction Y and face each other in the first direction X.

The semiconductor device 1 includes a drift region 6 of an n-type (first conductivity type) that is formed inside the semiconductor chip 2. The drift region 6 is preferably formed at least in a surface layer portion of the first main surface 3. In this embodiment, the drift region 6 is formed across an entirety of the semiconductor chip 2 and is exposed from the first main surface 3 and the first to fourth side surfaces 5A to 5D.

The drift region 6 may have an n-type impurity concentration of not less than 1.0×10¹³ cm⁻³ and not more than 1.0×10¹⁵ cm⁻³. In this embodiment, the drift region 6 is formed using a semiconductor substrate (that is, the semiconductor chip 2) of the n-type. The semiconductor substrate may have a single layer structure constituted of an FZ substrate formed via an FZ (floating zone) method or of an CZ substrate formed via a CZ (Czochralski) method.

The semiconductor device 1 includes a field stop region 7 of the n-type that is formed in a surface layer portion of the second main surface 4. The field stop region 7 has an n-type impurity concentration that exceeds the n-type impurity concentration of the drift region 6. The n-type impurity concentration of the field stop region 7 may be not less than 1.0×10¹⁴ cm⁻³ and not more than 1.0×10¹⁸ cm⁻³. The field stop region 7 is formed across an entirety of the surface layer portion of the second main surface 4 and is exposed from portions of the first to fourth side surfaces 5A to 5D.

The semiconductor device 1 includes a collector region 8 of a p-type (second conductivity type) that is formed in the surface layer portion of the second main surface 4. The collector region 8 may have a p-type impurity concentration of not less than 1.0×10¹⁶ cm⁻³ and not more than 1.0×10¹⁸ cm⁻³. More specifically, the collector region 8 is formed in the surface layer portion at the second main surface 4 side with respect to the field stop region 7 and is electrically connected to the field stop region 7. The collector region 8 is formed across an entirety of the surface layer portion of the second main surface 4 and is exposed from portions of the second main surface 4 and the first to fourth side surfaces 5A to 5D.

The semiconductor device 1 includes a body region 9 of the p-type that is formed in a surface layer portion of the first main surface 3. The body region 9 may have a p-type impurity concentration of not less than 1.0×10¹⁶ cm⁻³ and not more than 1.0×10¹⁸ cm⁻³. In the normal direction Z, the body region 9 faces the field stop region 7 (collector region 8) across the drift region 6.

The semiconductor device 1 includes a plurality of trench structures 10 formed at the first main surface 3. In plan view, the plurality of trench structures 10 are respectively formed as bands extending in the first direction X and at intervals in the second direction Y. The plurality of trench structures 10 are thereby formed as stripes extending in the first direction X in plan view. In the normal direction Z, the plurality of trench structures 10 face the field stop region 7 (collector region 8) across the drift region 6.

Each trench structure 10 has a first width W1. The first width W1 is a width in a direction (that is, the second direction Y) that is orthogonal to the direction in which the trench structure 10 extends. The first width W1 may be not less than 0.5 μm and not more than 3 μm. The first width W1 is preferably not less than 1 μm and not more than 2.5 μm.

A single trench structure 10 shall now be described. Specifically, the trench structure 10 includes a trench 11, a trench insulating film 12, and an embedded electrode 13. The trench 11 is dug in toward the second main surface 4 from the first main surface 3. The trench 11 penetrates through the body region 9 and reaches the drift region 6. The trench 11 is formed at an interval toward the first main surface 3 side from the field stop region 7.

The trench 11 includes a side wall and a bottom wall. The side wall of the trench 11 exposes the drift region 6 and the body region 9. The bottom wall of the trench 11 exposes the drift region 6. An angle that the side wall of the trench 11 forms inside the semiconductor chip 2 with the first main surface 3 may be not less than 90° and not more than 95°. The trench 11 may be formed to a convergent shape that narrows in opening width toward the bottom wall from an opening. The bottom wall of the trench 11 is preferably formed to a curved shape.

The trench insulating film 12 is formed as a film on the inner wall of the trench 11 and demarcates a recess space inside the trench 11. The trench insulating film 12 includes at least one of either of a silicon oxide film and a silicon nitride film. In this embodiment, the trench insulating film 12 has a single layer structure constituted of a silicon oxide film.

The embedded electrode 13 is embedded in the trench 11 across the trench insulating film 12. The embedded electrode 13 has an exposed surface exposed from the trench 11. The exposed surface of the embedded electrode 13 is positioned at the first main surface 3 side with respect to a bottom portion of the body region 9. The exposed surface of the embedded electrode 13 may be positioned at the bottom wall side of the trench 11 with respect to the first main surface 3. The exposed surface of the embedded electrode 13 may have a depression directed toward the bottom wall of the trench 11. The embedded electrode 13 may include conductive polysilicon.

The semiconductor device 1 includes a plurality of emitter regions 14 of the n-type that are formed in a surface layer portion of the body region 9. The emitter regions 14 have an n-type impurity concentration that exceeds the n-type impurity concentration of the drift region 6. The n-type impurity concentration of the emitter regions 14 may be not less than 1×10¹⁸ cm⁻³ and not more than 1×10²¹ cm⁻³.

The plurality of emitter regions 14 are respectively formed in regions of the surface layer portion of the body region 9 that extend along the side walls of the plurality of trench structures 10. Each of the plurality of emitter regions 14 is formed as a band extending along the corresponding trench structure 10 in plan view. The plurality of emitter regions 14 each face an embedded electrode 13 across the corresponding trench insulating film 12. Bottom portions of the plurality of emitter regions 14 are positioned in regions at the first main surface 3 side with respect to the bottom portion of the body region 9. The plurality of emitter regions 14 define channels of the IGBT between itself and the drift region 6 inside the body region 9.

The semiconductor device 1 includes a plurality of contact holes 15 that are each formed in a region between two neighboring trench structures 10 in the first main surface 3. The plurality of contact holes 15 are respectively formed at intervals in the second direction Y from the plurality of trench structures 10 in plan view. The plurality of contact holes 15 are each formed as a band extending in the first direction X in plan view. The plurality of contact holes 15 are formed alternately with the plurality of trench structures 10 in the second direction Y in a mode of sandwiching a single trench structure 10 in plan view.

In the first direction X, the plurality of contact holes 15 preferably have a length that is less than a length of the trench structures 10. The plurality of contact holes 15 respectively have a depth that crosses the emitter regions 14. Bottom walls of the plurality of contact holes 15 are respectively positioned in regions between the bottom portion of the body region 9 and the bottom portions of the emitter regions 14. The bottom walls of the plurality of contact holes 15 are positioned at the bottom portion side of the body region 9 with respect to the exposed surfaces of the embedded electrodes 13. The plurality of contact holes 15 expose the emitter regions 14 from both sides.

The plurality of contact holes 15 respectively have a second width W2. The second width W2 is a width in a direction (that is, the second direction Y) that is orthogonal to the direction in which the contact holes 15 extend. The second width W2 may be not less than 0.5 μm and not more than 5 μm. The second width W2 is preferably not less than 0.5 μm and not more than 3 μm. It is especially preferable for the second width W2 to exceed the first width W1.

The semiconductor device 1 includes a plurality of contact regions 16 of the p-type that are formed in the surface layer portion of the body region 9. Specifically, the plurality of contact regions 16 are respectively formed in regions of the surface layer portion of the body region 9 that extend along the plurality of contact holes 15. The contact regions 16 have a p-type impurity concentration that exceeds the p-type impurity concentration of the body region 9. The p-type impurity concentration of the contact regions 16 may be not less than 1×10¹⁸ cm⁻³ and not more than 1×10²¹ cm⁻³.

Each of the plurality of contact regions 16 covers the bottom wall of the corresponding contact hole 15. Bottom portions of the plurality of contact regions 16 are positioned in regions between the bottom portion of the body region 9 and the bottom portions of the emitter regions 14. Each of the plurality of contact regions 16 may cover a side wall of the corresponding contact hole 15.

The semiconductor device 1 includes a plurality of Ti silicide layers 17 that are formed in the surface layer portion of the body region 9. The plurality of Ti silicide layers 17 are each formed in a region between two neighboring trench structures 10 in the first main surface 3. Specifically, the plurality of Ti silicide layers 17 are respectively formed as films in regions that extend along wall surfaces of the contact holes 15 and at intervals from the plurality of trench structures 10. The plurality of Ti silicide layers 17 form ohmic contacts with the emitter regions 14 and the contact regions 16.

The semiconductor device 1 further includes a main surface insulating film 20 (insulating film) that covers the first main surface 3. In this embodiment, the main surface insulating film 20 has a laminated structure that includes a first insulating film 21 and a second insulating film 22. The first insulating film 21 covers the first main surface 3 and is connected to the trench insulating films 12. The first insulating film 21 includes the same insulating material as the trench insulating films 12. The second insulating film 22 covers the first insulating film 21. The second insulating film 22 has a thickness that exceeds a thickness of the first insulating film 21. The second insulating film 22 may have a single layer structure or a laminated structure that includes one of either or both of a silicon oxide film and a silicon nitride film.

The main surface insulating film 20 includes a plurality of penetrating holes 23 that expose the semiconductor chip 2. Specifically, the plurality of penetrating holes 23 include a plurality of emitter penetrating holes 24 and a plurality of gate penetrating holes (not shown). The plurality of emitter penetrating holes 24 are respectively formed as bands extending along the plurality of contact holes 15 in plan view and are respectively in communication with the plurality of contact holes 15. The plurality of emitter penetrating holes 24, together with the plurality of contact holes 15, each demarcate a single emitter opening 25. The plurality of gate penetrating holes (not shown) are formed as gate openings that expose the embedded electrodes 13.

The semiconductor device 1 includes a first terminal electrode 30 (electrode) formed on the main surface insulating film 20 (insulator). The first terminal electrode 30 is an electrode that is connected to a lead wire (for example, a bond wire), etc. Specifically, the first terminal electrode 30 includes a gate terminal 31 and an emitter terminal 32.

The gate terminal 31 includes a main body portion 33 and a wiring portion 34. The main body portion 33 is disposed at a central portion at the first side surface 5A side in plan view. The main body portion 33 may instead be disposed at a corner portion of the main surface insulating film 20 in plan view. The main body portion 33 may be formed to a quadrilateral shape in plan view.

The wiring portion 34 is led out as a band on the main surface insulating film 20 to arbitrary regions from the main body portion 33. In this embodiment, the wiring portion 34 is formed to extend along the first side surface 5A, the third side surface 5C, and the fourth side surface 5D in plan view and demarcates the semiconductor chip 2 from three directions. The wiring portion 34 enters into the corresponding plurality of gate penetrating holes (not shown) from above the main surface insulating film 20. The wiring portion 34 is electrically connected to the plurality of embedded electrodes 13 inside the plurality of gate penetrating holes (not shown). A gate potential applied to the main body portion 33 is transmitted to the embedded electrodes 13 via the wiring portion 34.

The emitter terminal 32 is formed at a region on the main surface insulating film 20 that is demarcated by the gate terminal 31. The emitter terminal 32 enters into a plurality of emitter openings 25 from above the main surface insulating film 20. The emitter terminal 32 is electrically connected to the body region 9, the emitter regions 14, and the contact regions 16 inside the plurality of emitter openings 25 (specifically, the contact holes 15). An emitter potential applied to the emitter terminal 32 is transmitted to the body region 9, the emitter regions 14, and the contact regions 16.

Referring to FIG. 5 and FIG. 6, the first terminal electrode 30 has a laminated structure that includes a Ti film 41 (titanium film), a TiN film 42 (titanium nitride film), a TiAl alloy film 43 (titanium aluminum alloy film) and the Al-based metal film 44 (aluminum-based metal film) that are laminated in that order from the chip side. In the following, the specific structure of the first terminal electrode 30 shall be described by taking the structure of the emitter terminal 32 as an example. Also in the following, the structure inside a single emitter opening 25 shall be described specifically.

The Ti film 41 is formed as a film on the main surface insulating film 20. The Ti film 41 enters into the emitter opening 25 from above the main surface insulating film 20 and is electrically connected to the semiconductor chip 2 inside the emitter opening 25. Specifically, the Ti film 41 includes a first surface at the semiconductor chip 2 side and a second surface at an opposite side to the first surface. The Ti film 41 is formed as a film with which the first surface and the second surface are oriented along an outer surface of the main surface insulating film 20 and an inner wall of the emitter opening 25. The Ti film 41 thereby includes a film portion positioned inside the emitter opening 25 and a film portion positioned outside the emitter opening 25.

More specifically, the Ti film 41 includes a first side wall portion 41A and a first bottom wall portion 41B that demarcate a recess space inside the emitter opening 25. The first side wall portion 41A covers a side wall of the emitter opening 25 as a film. Specifically, the first side wall portion 41A covers a wall surface of the penetrating hole 23 and the side wall of the contact hole 15 and is electrically connected to the Ti silicide layer 17. The first bottom wall portion 41B covers a bottom wall of the emitter opening 25 (specifically, the bottom wall of the contact hole 15) as a film and is electrically connected to the Ti silicide layer 17. The first surface and the second surface of the first bottom wall portion 41B are positioned at the bottom wall side of the contact hole 15 with respect to the first main surface 3.

The Ti film 41 is thus electrically connected to the Ti silicide layer 17 at the first side wall portion 41A and the first bottom wall portion 41B. The Ti film 41 forms an ohmic contact with the semiconductor chip 2 (specifically, the contact region 16) via the Ti silicide layer 17. A portion or an entirety of the first bottom wall portion 41B may be made integral to the Ti silicide layer 17. The Ti film 41 has a first thickness T1. The first thickness T1 is a thickness of the Ti film 41 that connects the first surface and the second surface with the shortest distance. The first thickness T1 may be not less than 10 Å and not more than 1000 Å. The first thickness T1 is preferably not less than 50 Å and not more than 500 Å.

The TiN film 42 is formed as a film on the Ti film 41. The TiN film 42 enters into the emitter opening 25 from above the Ti film 41 and is electrically connected to the Ti film 41 inside and outside the emitter opening 25. Specifically, the TiN film 42 includes a third surface at the semiconductor chip 2 side and a fourth surface at an opposite side to the third surface. The TiN film 42 is formed as a film with which the third surface and the fourth surface are oriented along an outer surface of the Ti film 41 (that is, the second surface). The TiN film 42 thereby includes a film portion positioned inside the emitter opening 25 and a film portion positioned outside the emitter opening 25.

More specifically, the TiN film 42 includes a second side wall portion 42A and a second bottom wall portion 42B that demarcate a recess space inside the emitter opening 25. The second side wall portion 42A covers, as a film, the wall surface of the penetrating hole 23 and the side wall of the contact hole 15 across the first side wall portion 41A of the Ti film 41. The second bottom wall portion 42B covers, as a film, the bottom wall of the contact hole 15 across the first bottom wall portion 41B of the Ti film 41. The third surface and the fourth surface of the second bottom wall portion 42B are positioned at the bottom wall side of the contact hole 15 with respect to the first main surface 3.

The TiN film 42 is thus electrically connected to the Ti silicide layer 17 via the Ti film 41. The TiN film 42 has a second thickness T2. The second thickness T2 is a thickness of the TiN film 42 that connects the third surface and the fourth surface with the shortest distance. The second thickness T2 may be not less than 100 Å and not more than 2000 Å. The second thickness T2 is preferably not less than 100 Å and not more than 1000 Å. The second thickness T2 may be not less than the first thickness T1 (T1≤T3).

The TiAl alloy film 43 is formed as a film on the TiN film 42. The TiAl alloy film 43 enters into the emitter opening 25 from above the TiN film 42 and is electrically connected to the TiN film 42 inside and outside the emitter opening 25. Specifically, the TiAl alloy film 43 includes a fifth surface at the semiconductor chip 2 side and a sixth surface at an opposite side to the fifth surface. The TiAl alloy film 43 is formed as a film with which the fifth surface and the sixth surface are oriented along an outer surface of the TiN film 42 (that is, the fourth surface). The TiAl alloy film 43 thereby includes a film portion positioned inside the emitter opening 25 and a film portion positioned outside the emitter opening 25.

More specifically, the TiAl alloy film 43 includes a third side wall portion 43A and a third bottom wall portion 43B that demarcate a recess space inside the emitter opening 25. The third side wall portion 43A covers, as a film, the wall surface of the penetrating hole 23 and the side wall of the contact hole 15 across the first side wall portion 41A of the Ti film 41 and the second side wall portion 42A of the TiN film 42. The third bottom wall portion 43B covers, as a film, the bottom wall of the contact hole 15 across the first bottom wall portion 41B of the Ti film 41 and the second bottom wall portion 42B of the TiN film 42.

The fifth surface and the sixth surface of the third bottom wall portion 43B are positioned at the bottom wall side of the contact hole 15 with respect to a main surface of the main surface insulating film 20. The fifth surface of the third bottom wall portion 43B is positioned at the bottom wall side of the contact hole 15 with respect to the first main surface 3. The sixth surface of the third bottom wall portion 43B may be positioned at the bottom wall side of the contact hole 15 with respect to the first main surface 3 or may be positioned at the main surface insulating film 20 side with respect to the first main surface 3.

The TiAl alloy film 43 is thus electrically connected to the Ti silicide layer 17 via the TiN film 42 and the Ti film 41. The TiAl alloy film 43 has a third thickness T3. The third thickness T3 is a thickness of the TiAl alloy film 43 that connects the fifth surface and the sixth surface with the shortest distance.

The third thickness T3 exceeds the first thickness T1 (T1<T3). The third thickness T3 exceeds the second thickness T2 (T2<T3). The third thickness T3 is preferably not less than a total value T1+T2 of the first thickness T1 and the second thickness T2 (T1+T2≤T3). The third thickness T3 may be not less than 200 Å and not more than 10000 Å. The third thickness T3 is preferably not less than 1000 Å and not more than 8000 Å.

The Al-based metal film 44 is a metal film including aluminum as a main component. The Al-based metal film 44 may include at least one among a pure Al film (Al of a purity of not less than 99%), an AlSi alloy film, an AlCu alloy film and an AlSiCu alloy film. In this embodiment, the Al-based metal film 44 is constituted of an AlSiCu alloy film. If the Al-based metal film 44 is constituted of an Al-based alloy, the specific gravity of Al is arbitrary.

The Al-based metal film 44 is formed as a film on the TiAl alloy film 43. The Al-based metal film 44 enters into the emitter opening 25 from above the TiAl alloy film 43 and is electrically connected to the TiAl alloy film 43 inside and outside the emitter opening 25. Specifically, the Al-based metal film 44 includes a seventh surface at the semiconductor chip 2 side and an eighth surface at an opposite side to the seventh surface. The Al-based metal film 44 is formed as a film with which the seventh surface and the eighth surface are oriented along an outer surface of the TiAl alloy film 43 (that is, the sixth surface).

The Al-based metal film 44 thereby includes a film portion positioned inside the emitter opening 25 and a film portion positioned outside the emitter opening 25. The film portion of the Al-based metal film 44 that is positioned inside the emitter opening 25 is made integral inside the emitter opening 25 and refills the recess space. The portion of the Al-based metal film 44 that is positioned inside the emitter opening 25 is thereby formed as an anchor portion engaged with the recess space demarcated by the TiAl alloy film 43.

The seventh surface of the Al-based metal film 44 includes a portion positioned inside the emitter opening 25 and a portion positioned outside the emitter opening 25. On the other hand, an entirety of the eighth surface of the TiAl alloy film 43 is positioned outside the emitter opening 25. A portion of the eighth surface of the TiAl alloy film 43 that faces the emitter opening 25 is depressed toward the semiconductor chip 2 side.

The Al-based metal film 44 is thus electrically connected to the Ti silicide layer 17 via the Ti film 41, the TiN film 42, and the TiAl alloy film 43. The Al-based metal film 44 has a fourth thickness T4. The fourth thickness T4 is a thickness of the Al-based metal film 44 that connects the seventh surface and the eighth surface with the shortest distance. The fourth thickness T4 exceeds the third thickness T3 (T3<T4). The fourth thickness T4 may be not less than 1 μm and not more than 10 μm.

As described above, a portion of the emitter terminal 32 that is positioned inside the emitter opening 25 is formed of the laminated structure that includes the Ti film 41, the TiN film 42, the TiAl alloy film 43 and the Al-based metal film 44. Although a specific description shall be omitted, a portion of the gate terminal 31 that is positioned inside a gate opening (not shown) has the same form as the portion of the emitter terminal 32 positioned inside the emitter opening 25. That is, like the emitter terminal 32, a portion of the gate terminal 31 positioned inside a penetrating hole 23 (that is, a gate opening (not shown)) is formed of the laminated structure that includes the Ti film 41, the TiN film 42, the TiAl alloy film 43 and the Al-based metal film 44.

Referring to FIG. 7, the first terminal electrode 30 has a plurality of whiskers 45 that are constituted of protrusions on an outer surface of the Al-based metal film 44 (that is, the eighth surface). Specifically, the plurality of whiskers 45 are constituted of an Al-based metal crystalline substance that has grown to needle shapes, columnar shapes, linear shapes, rod shapes, etc., from the eighth surface of the Al-based metal film 44. Although a size of the whiskers 45 is variable, it falls within a range of not less than 0.01 μm to not more than 1 μm in many cases. In the following, the number of whiskers 45 per unit square centimeter [whiskers/cm²] shall be referred to as the “whisker density DW.”

As shall be described later, the whisker density DW is adjusted by a temperature T during forming of the Al-based metal film 44. The first terminal electrode 30 has a whisker density DW of not more than 5000 whiskers/cm². The whisker density DW may be not more than 1000 whiskers/cm². The whisker density DW may be not more than 500 whiskers/cm². The whisker density DW may be not more than 250 whiskers/cm². The whisker density DW may be not more than 50 whiskers/cm². The whisker density DW may be not more than 10 whiskers/cm².

Referring to FIG. 2, the semiconductor device 1 includes the top insulating film 50 formed on the main surface insulating film 20. The top insulating film 50 covers the first terminal electrode 30 partially such as to expose portions of the first terminal electrode 30. In this embodiment, the top insulating film 50 has a laminated structure that includes an inorganic insulating film 51 and an organic insulating film 52 that are laminated in that order from the main surface insulating film 20 side. Whether or not the inorganic insulating film 51 is provided is arbitrary and a top insulating film 50 that does not have the inorganic insulating film 51 may be adopted instead.

The inorganic insulating film 51 may include at least one among a silicon oxide film and a silicon nitride film. The inorganic insulating film 51 preferably includes an insulating material differing from that of the main surface insulating film 20. In this embodiment, the inorganic insulating film 51 has a single layer structure constituted of a silicon nitride film. The inorganic insulating film 51 is formed as a film along outer surfaces of the main surface insulating film 20 and the first terminal electrode 30. A thickness of the inorganic insulating film 51 may be not less than 0.1 μm and not more than 5 μm.

The organic insulating film 52 may include a photosensitive resin. The photosensitive resin may be of a negative type or a positive type. The organic insulating film 52 may include at least one among a polyimide, a polyamide, and a polybenzoxazole. In this embodiment, the organic insulating film 52 includes a polybenzoxazole. The organic insulating film 52 is formed as a film along an outer surface of the inorganic insulating film 51. A thickness of the organic insulating film 52 may be not less than 1 μm and not more than 20 μm.

The top insulating film 50 includes a plurality of pad openings 53 that expose the first terminal electrode 30. Specifically, the plurality of pad openings 53 include a gate pad opening 54 and an emitter pad opening 55. The gate pad opening 54 exposes a portion of the gate terminal 31 as a gate pad portion. The emitter pad opening 55 exposes a portion of the emitter terminal 32 as an emitter pad portion.

The top insulating film 50 has a peripheral edge that is formed at intervals inward from the first to fourth side surfaces 5A to 5D. The peripheral edge of the top insulating film 50, together with the first to fourth side surfaces 5A to 5D, demarcate a dicing street 56 that exposes the main surface insulating film 20. A width of the dicing street 56 may be not less than 1 μm and not more than 25 μm. The width of the dicing street 56 is a width in a direction orthogonal to a direction in which the dicing street 56 extends.

The semiconductor device 1 includes a second terminal electrode 57 that is formed on the second main surface 4. The second terminal electrode 57 covers an entirety of the second main surface 4 and is electrically connected to the collector region 8. That is, second terminal electrode 57 is continuous to the first to fourth side surfaces 5A to 5D. The second terminal electrode 57 forms an ohmic contact with the collector region 8. A collector potential applied to the second terminal electrode 57 is transmitted to the collector region 8.

The second terminal electrode 57 includes a Ti film 58 as an ohmic electrode. In this embodiment, the second terminal electrode 57 further includes an Ni film 59, a Pd film 60, an Au film 61, and an Ag film 62 that are laminated in that order from the Ti film 58 side. The second terminal electrode 57 does not necessarily have to have all of the Ni film 59, the Pd film 60, the Au film 61, and the Ag film 62. The second terminal electrode 57 may include at least one among the Ni film 59, the Pd film 60, the Au film 61, and the Ag film 62 on the Ti film 58.

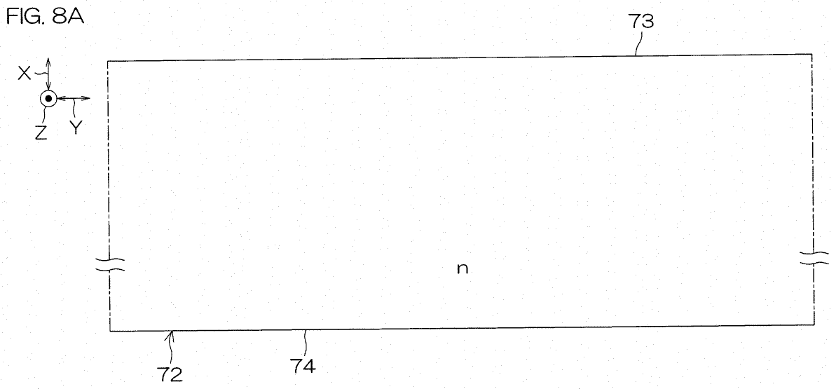

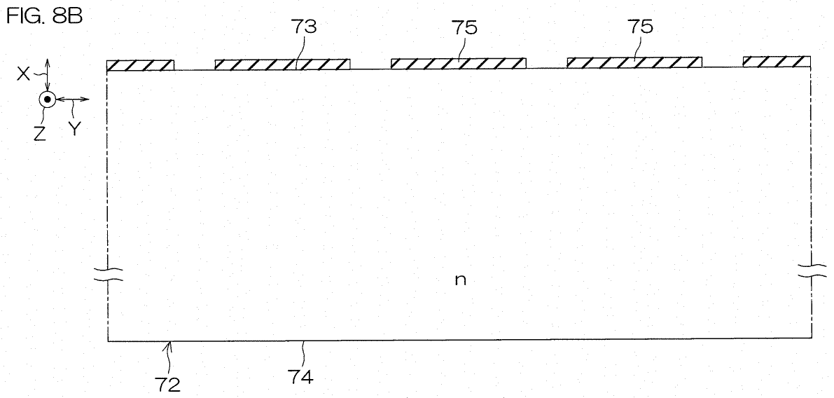

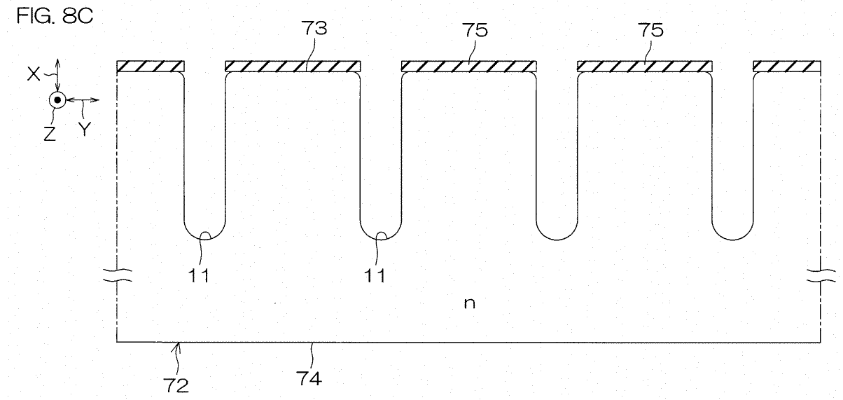

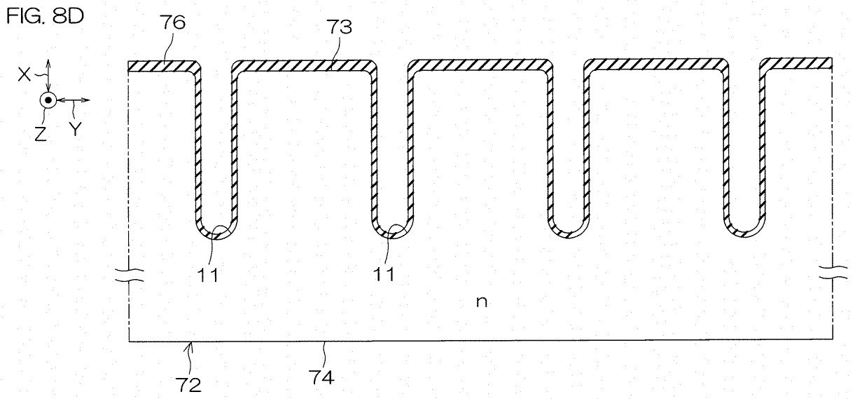

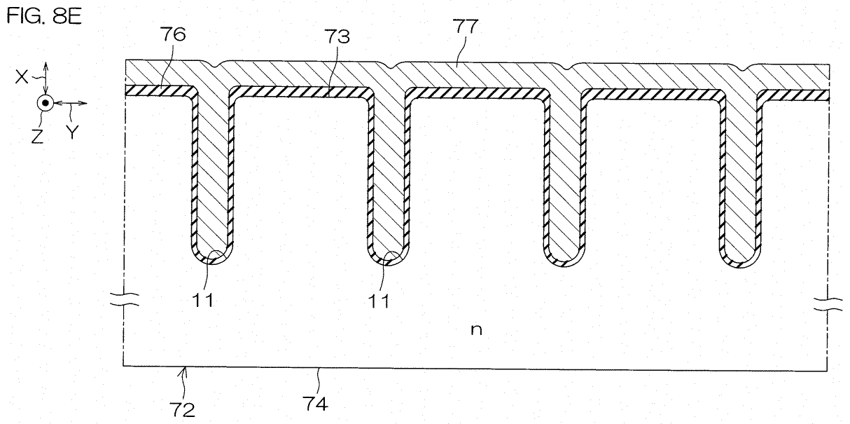

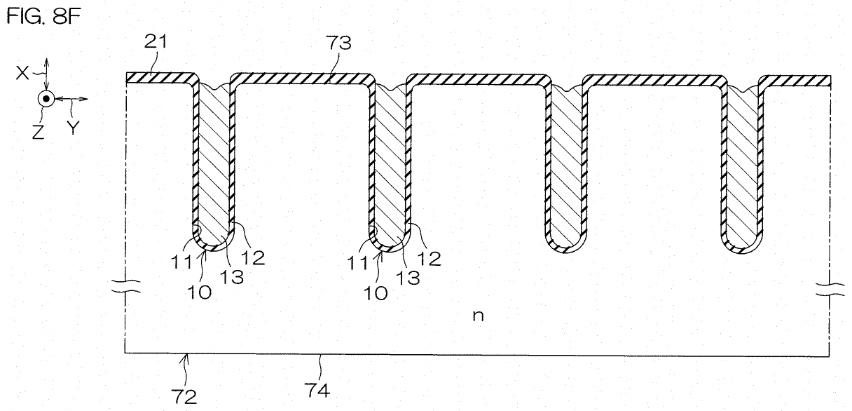

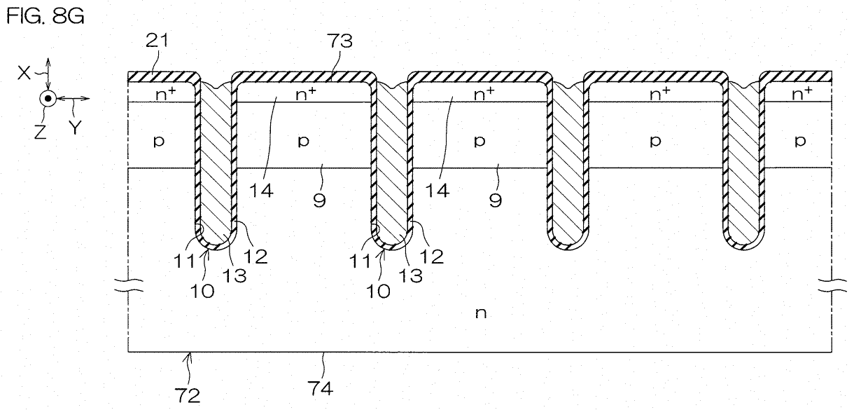

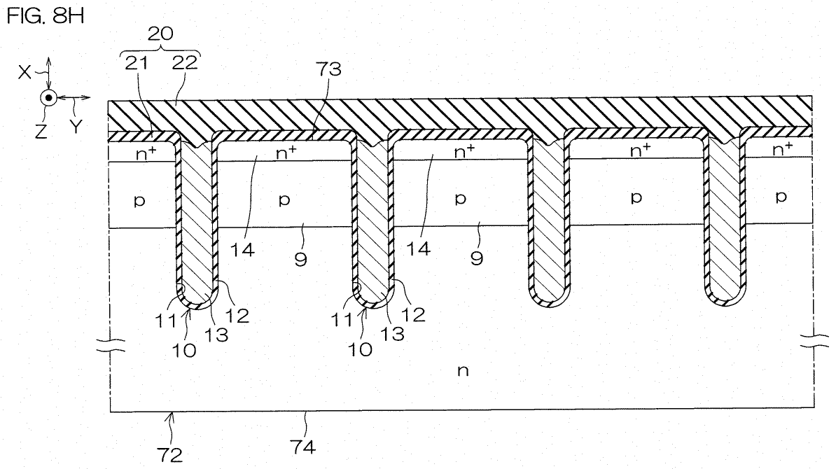

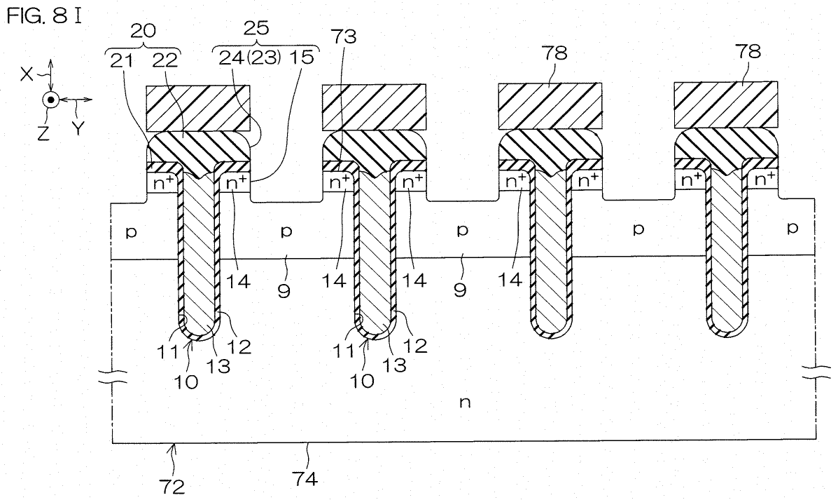

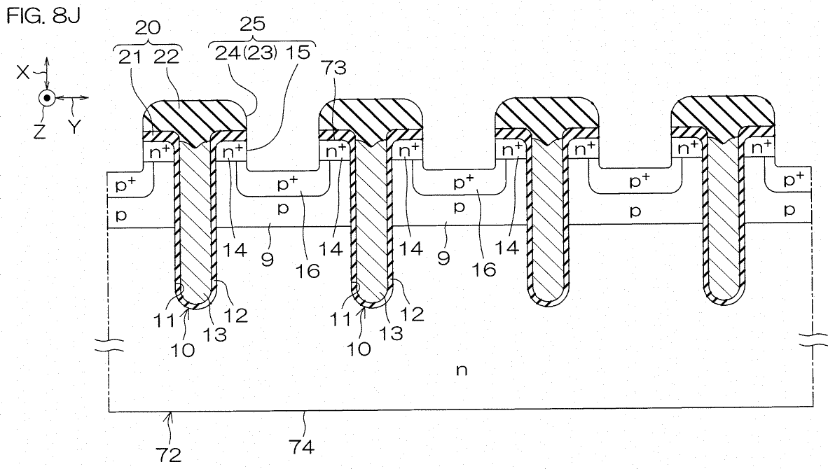

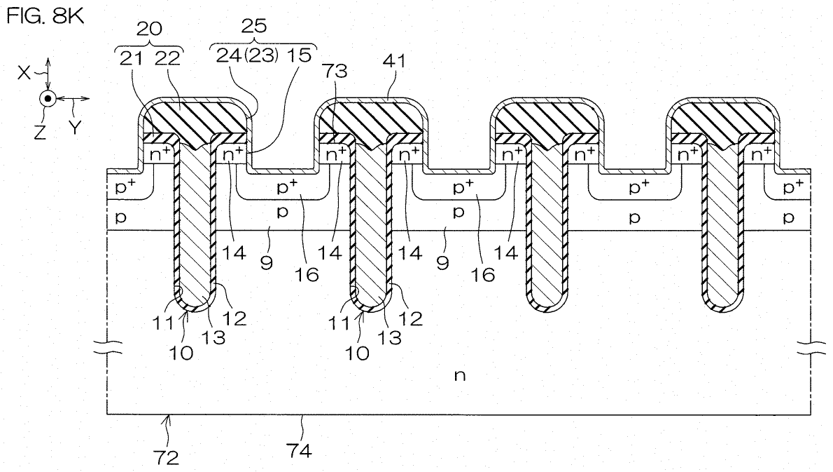

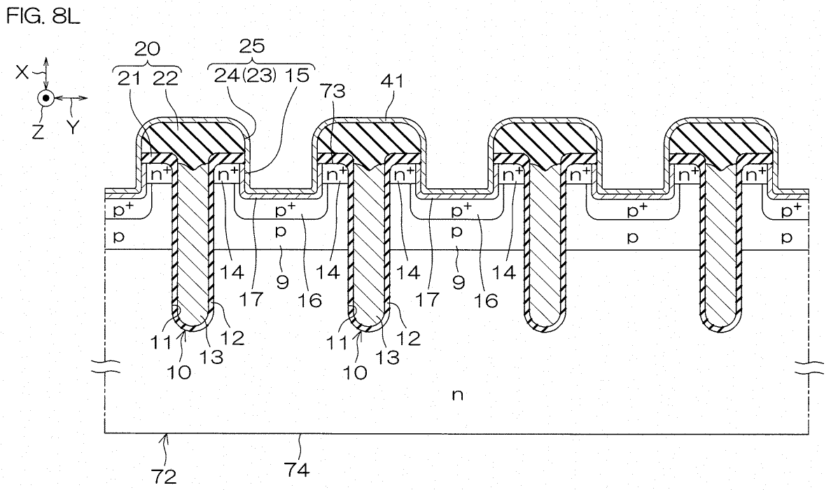

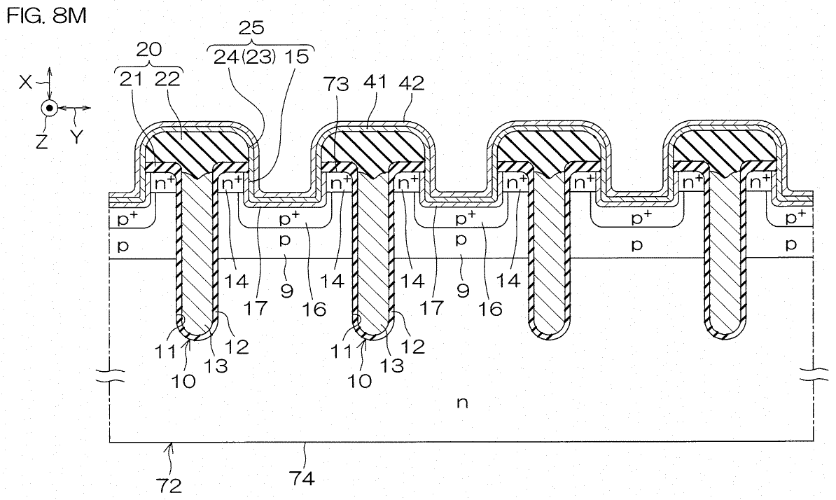

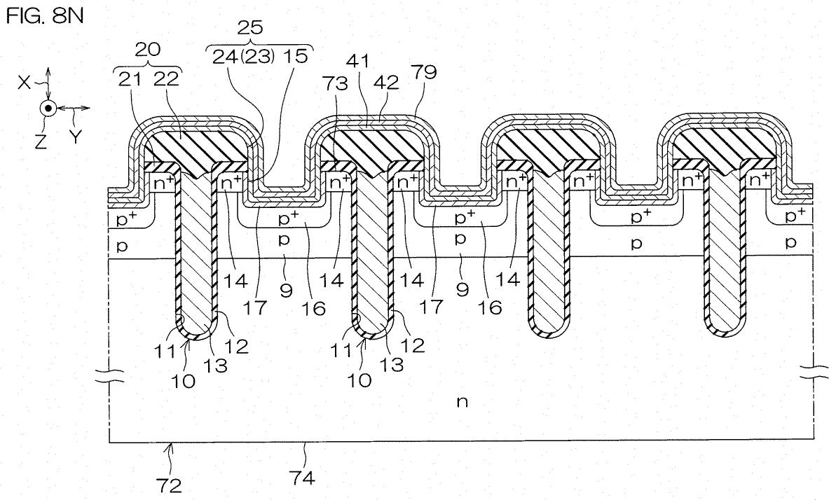

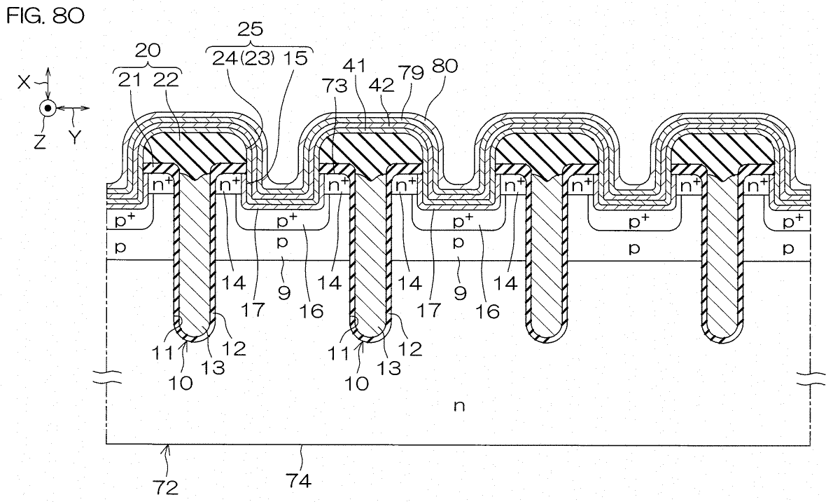

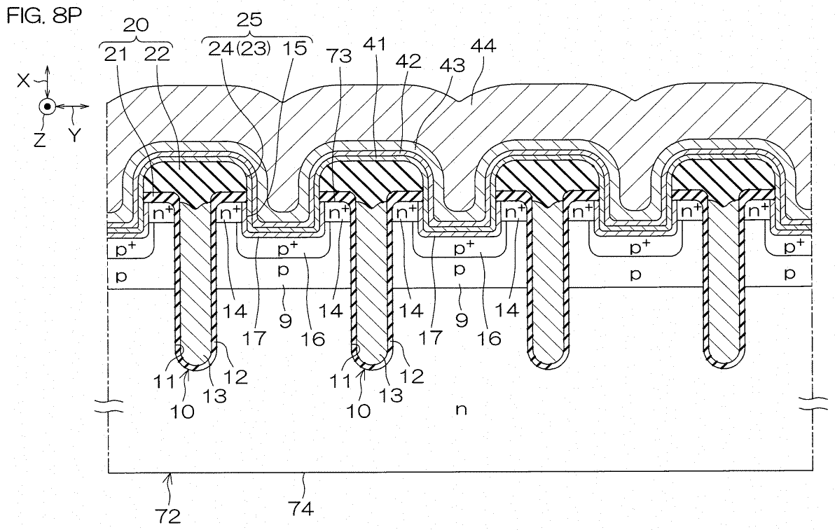

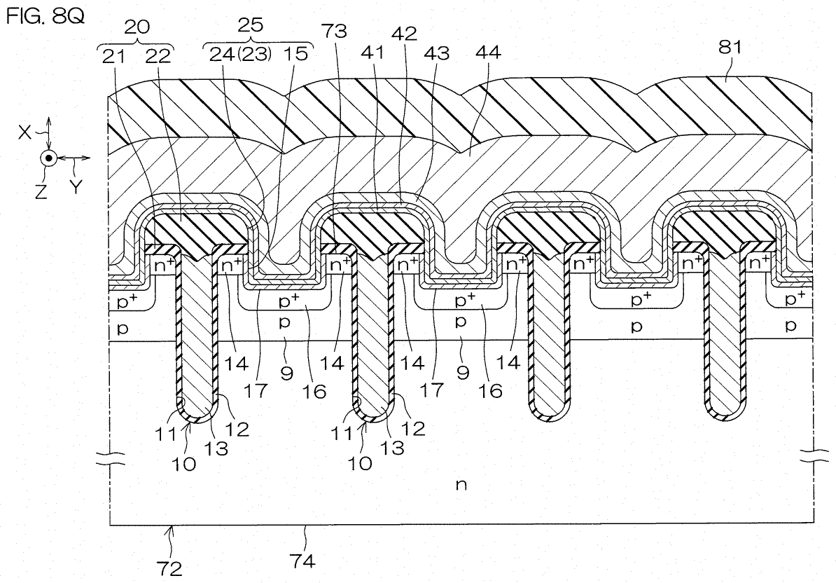

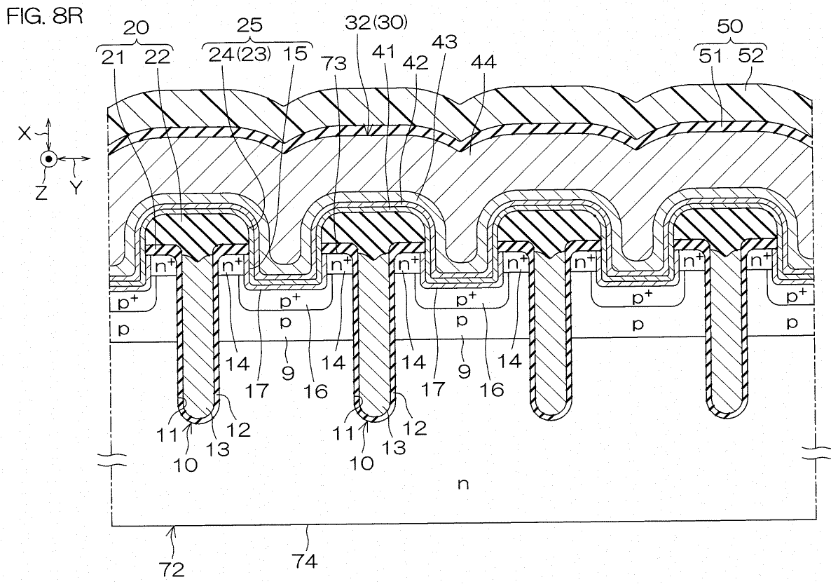

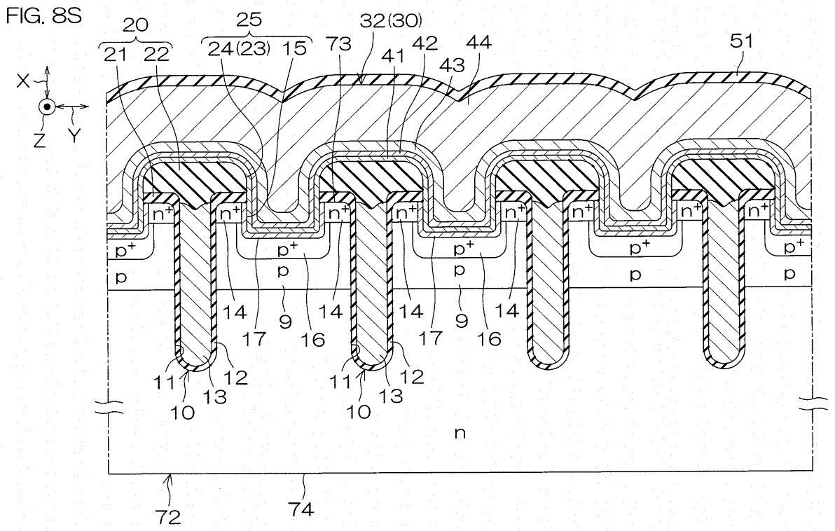

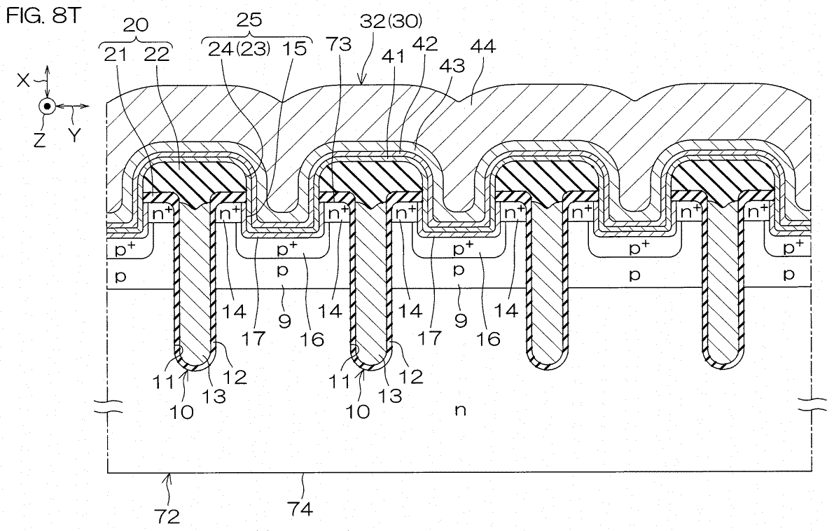

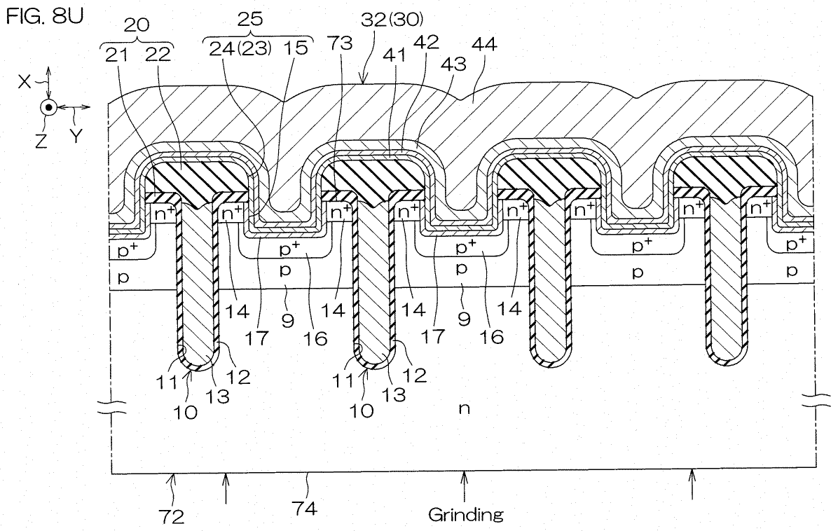

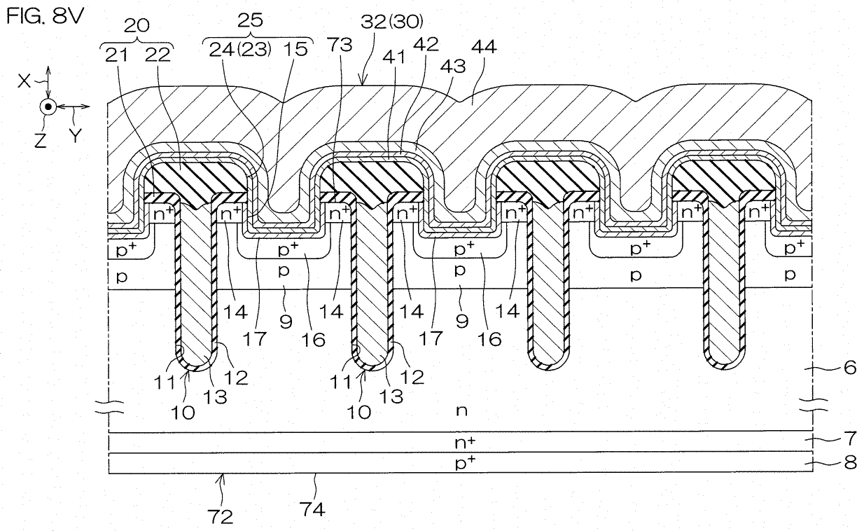

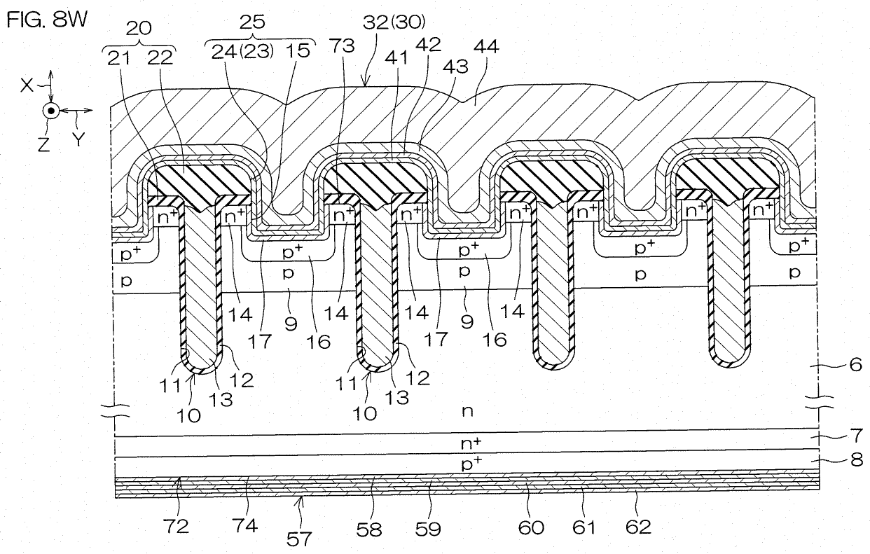

FIG. 8A to FIG. 8W are sectional views of an example of a method for manufacturing the semiconductor device 1 shown in FIG. 1. FIG. 8A to FIG. 8W are sectional views of a portion corresponding to FIG. 5.

Referring to FIG. 8A, a wafer 72 that is to be a base of the semiconductor chip 2 is prepared. The wafer 72 may have a single layer structure constituted of an FZ wafer formed through an FZ method or a CZ wafer formed through a CZ method. The wafer 72 has a first wafer main surface 73 at one side and a second wafer main surface 74 at another side. The first wafer main surface 73 and the second wafer main surface 74 correspond respectively to the first main surface 3 and the second main surface 4 of the semiconductor chip 2.

Next, referring to FIG. 8B, a hard mask 75 having a predetermined pattern is formed on the first wafer main surface 73. The hard mask 75 exposes regions in which the plurality of trenches 11 are to be formed and covers regions besides these. The hard mask 75 may be formed by a thermal oxidation treatment method and/or a CVD (chemical vapor deposition) method. The pattern of the hard mask 75 may be formed by a wet etching method and/or a dry etching method via a mask (not shown).

Next, referring to FIG. 8C, the trenches 11 are formed. The trenches 11 are formed by partially removing the first wafer main surface 73 by an etching method via the hard mask 75. The etching method may be formed by a wet etching method and/or a dry etching method. The etching method is preferably an isotropic wet etching method and/or an isotropic dry etching method. The hard mask 75 is thereafter removed.

Next, referring to FIG. 8D, a base insulating film 76 that is to be a base of the trench insulating films 12 and the first insulating film 21 is formed on the first wafer main surface 73. In this embodiment, the base insulating film 76 is constituted of a silicon oxide film. The base insulating film 76 is formed by a thermal oxidation treatment method and/or a CVD method (in this embodiment, by the thermal oxidation method). The base insulating film 76 is formed as a film on the first wafer main surface 73 and the inner walls of the trenches 11.

Next, referring to FIG. 8E, a base conductor film 77 that is to be a base of the embedded electrodes 13 is formed on the first wafer main surface 73. In this embodiment, the base conductor film 77 is formed of a conductive polysilicon. The base conductor film 77 may be formed by laminating a conductor by a CVD method. The base conductor film 77 is embedded in the trenches 11 across the base insulating film 76 and covers the first wafer main surface 73 across the base insulating film 76.

Next, referring to FIG. 8F, unnecessary portions of the base conductor film 77 are removed by an etching method. The unnecessary portions of the base conductor film 77 are removed until the base insulating film 76 is exposed. The etching method may be a wet etching method and/or a dry etching method. Portions of the base insulating film 76 that cover the inner walls of the trenches 11 thereby become the trench insulating films 12. Also, a portion of the base insulating film 76 that covers the first wafer main surface 73 becomes the first insulating film 21. Also, portions of the base conductor film 77 that remain inside the trenches 11 become the embedded electrodes 13. The plurality of trench structures 10 are thereby formed in the first wafer main surface 73.

Next, referring to FIG. 8G, the body region 9 and the emitter regions 14 are formed in a surface layer portion of the first wafer main surface 73. In the step of forming the body region 9, a p-type impurity is selectively introduced into the surface layer portion of the first wafer main surface 73 by an ion implantation method via an ion implantation mask (not shown). In the step of forming the emitter regions 14, an n-type impurity is selectively introduced into the surface layer portion of the body region 9 by an ion implantation method via an ion implantation mask (not shown).

An order of the step of forming the body region 9 and the step of forming the emitter regions 14 is arbitrary. Also, the step of forming the body region 9 and the step of forming the emitter regions 14 may be performed at an arbitrary timing and do not necessarily have to be performed at this timing. For example, the step of forming the body region 9 and the step of forming the emitter regions 14 may be performed before the step of forming the trenches 11.

Next, referring to FIG. 8H, the second insulating film 22 is formed on the first insulating film 21 such as to cover the plurality of trench structures 10. In this embodiment, the second insulating film 22 includes at least one among a silicon oxide film and a silicon nitride film. The second insulating film 22 may be formed by laminating an insulator by a CVD method. The main surface insulating film 20 that is constituted of the first insulating film 21 and the second insulating film 22 is thereby formed.

Next, referring to FIG. 8I, a resist mask 78 having a predetermined pattern is formed on the main surface insulating film 20. The resist mask 78 exposes regions of the main surface insulating film 20 in which the plurality of penetrating holes 23 (including the emitter penetrating holes 24 and the gate penetrating holes (not shown)) and covers regions besides these. Next, unnecessary portions of the main surface insulating film 20 are removed by an etching method via the resist mask 78. The etching method may be a wet etching method and/or a dry etching method. The plurality of penetrating holes 23 are thereby formed in the main surface insulating film 20. The resist mask 78 is thereafter removed.

Next, portions of the first wafer main surface 73 exposed from the plurality of emitter penetrating holes 24 are removed by an etching method via the main surface insulating film 20. The etching method may be a wet etching method and/or a dry etching method. The plurality of contact holes 15 that, together with the plurality of emitter penetrating holes 24, respectively demarcate the emitter openings 25 are thereby formed in the first wafer main surface 73. In the step of forming the contact holes 15, unnecessary portions of the first wafer main surface 73 may be removed using the resist mask 78 described above.

Next, referring to FIG. 8J, the contact regions 16 are formed in regions of the surface layer portion of the body region 9 that are oriented along the contact holes 15. In the step of forming the contact regions 16, a p-type impurity is introduced into the regions of the surface layer portion of the body region 9 that are oriented along the contact holes 15 by an ion implantation method via an ion implantation mask (not shown).

Next, referring to FIG. 8K, the Ti film 41 is formed on the first wafer main surface 73. The Ti film 41 is formed by a vapor deposition method and/or a sputtering method (in this embodiment, by the sputtering method). The Ti film 41 is formed as a film on the main surface insulating film 20 and enters into the plurality of penetrating holes 23 (the emitter openings 25 and the gate openings (not shown)) from above the main surface insulating film 20. Inside the penetrating holes 23, the Ti film 41 is electrically connected to the wafer 72 and the embedded electrodes 13. A description of the specific form of the Ti film 41 is as has been given above and shall be omitted.

Next, referring to FIG. 8L, the Ti silicide layers 17 are formed at connection portions of the Ti film 41 and the first wafer main surface 73 by an RTA (rapid thermal annealing) method.

Next, referring to FIG. 8M, the TiN film 42 is formed on the Ti film 41. The TiN film 42 is formed by a vapor deposition method and/or a sputtering method (in this embodiment, by the sputtering method). The TiN film 42 is formed as a film on the Ti film 41 and covers the Ti film 41 inside and outside the emitter openings 25. Inside the plurality of penetrating holes 23, the TiN film 42 is electrically connected to the wafer 72 and the embedded electrodes 13. A description of the specific form of the TiN film 42 is as has been given above and shall be omitted.

Next, referring to FIG. 8N, a base Ti film 79 that is to be a base of the TiAl alloy film 43 is formed on the TiN film 42. The base Ti film 79 may also be referred to as an “upper Ti film” that is position at an upper side with respect to the Ti film 41. The base Ti film 79 is formed by a vapor deposition method and/or a sputtering method (in this embodiment, by the sputtering method). The base Ti film 79 is formed as a film on the TiN film 42 and covers the TiN film 42 inside and outside the emitter openings 25. A thickness of the base Ti film 79 may be not less than 100 Å and not more than 1000 Å. The thickness of the base Ti film 79 is preferably not less than 100 Å and not more than 500 Å.

Next, referring to FIG. 8O, an Al-based metal 80 is deposited on the base Ti film 79 by a high-temperature sputtering method. The Al-based metal 80 becomes a base of the TiAl alloy film 43 and the Al-based metal film 44. The Al-based metal 80 includes at least one among pure Al, an AlSi alloy, an AlCu alloy and an AlSiCu alloy. The high-temperature sputtering method is performed at the temperature T at which the Al-based metal 80 becomes alloyed with the base Ti film 79. In this embodiment, the Al-based metal 80 is deposited on the base Ti film 79 at the temperature T of not less than 350° C. and not more than 480° C. The temperature T is preferably not less than 350° C. and not more than 460° C. The temperature T is especially preferably not less than 350° C. and not more than 440° C.

The step of forming the TiAl alloy film 43 preferably includes a step where the Al-based metal 80 is deposited on the base Ti film 79 without exposing the base Ti film 79 to an oxygen atmosphere (that is, without exposure to atmosphere), after the base Ti film 79 is formed. The Al-based metal 80 can thereby be deposited on and alloyed with the base Ti film 79 that is suppressed in oxidation.

After forming the base Ti film 79, the Al-based metal 80 may continue to be deposited on the base Ti film 79 inside the same chamber. Also, after forming the base Ti film 79, the wafer 72 may be transferred to another chamber in a manner such as not to expose the base Ti film 79 to an oxygen atmosphere and the Al-based metal 80 may be deposited on the base Ti film 79 in the other chamber. Through this step, the Al-based metal 80 is alloyed with the base Ti film 79 and the TiAl alloy film 43 is formed on the TiN film 42. A description of the specific form of the TiAl alloy film 43 is as has been given above and shall be omitted.

Next, referring to FIG. 8P, the Al-based metal 80 is continued to be deposited on the TiAl alloy film 43 by the high-temperature sputtering method. That is, the step of depositing the Al-based metal 80 is continued even after the alloying reaction of the Al-based metal 80 and the base Ti film 79 ends. The Al-based metal film 44 is thereby formed on the TiAl alloy film 43. The Al-based metal film 44 is formed on the TiAl alloy film 43 and covers the TiAl alloy film 43 inside and outside the emitter openings 25. A description of the specific form of the Al-based metal film 44 is as has been given above and shall be omitted.

Next, referring to FIG. 8Q, a resist mask 81 having a predetermined pattern is formed on the Al-based metal film 44. The resist mask 81 covers regions of the Al-based metal film 44 in which the first terminal electrode 30 is to be formed and exposes regions besides these. Next, unnecessary portions of the Al-based metal film 44 are removed by an etching method via the resist mask 81. The etching method may be a wet etching method and/or a dry etching method. The resist mask 81 is thereafter removed.

Next, the TiAl alloy film 43, the TiN film 42 and the Ti film 41 are removed by an etching method using the Al-based metal film 44 as a mask. If the TiAl alloy film 43 is removed in the step of removing the Al-based metal film 44, the step of removing the TiAl alloy film 43 may be omitted. The first terminal electrode 30 is thereby formed on the main surface insulating film 20.

Next, referring to FIG. 8R, the top insulating film 50 that covers the first terminal electrode 30 is formed on the main surface insulating film 20. The step of forming the top insulating film 50 includes a step of forming the inorganic insulating film 51 and a step of forming the organic insulating film 52. In this embodiment, the inorganic insulating film 51 is constituted of a silicon nitride film. The inorganic insulating film 51 may be formed by laminating an insulator by a CVD method. In this embodiment, the organic insulating film 52 is constituted of a photosensitive resin. The organic insulating film 52 is formed by coating the photosensitive resin onto the inorganic insulating film 51.

Next, referring to FIG. 8S, unnecessary portions of the organic insulating film 52 are removed by an exposing step and a developing step. Removed portions corresponding to the gate pad opening 54, the emitter pad opening 55, and the dicing street 56 are thereby formed in the organic insulating film 52.

Next, referring to FIG. 8T, portions of the inorganic insulating film 51 that are exposed from the organic insulating film 52 are removed. The inorganic insulating film 51 may be removed by an etching method using the organic insulating film 52 as a mask. The etching method may be a wet etching method and/or a dry etching method. The gate pad opening 54, the emitter pad opening 55, and the dicing street 56 are thereby formed in the top insulating film 50.

Next, referring to FIG. 8U, the wafer 72 is thinned to a desired thickness by grinding of the second wafer main surface 74. The grinding of the second wafer main surface 74 may be performed by a CMP (chemical mechanical polishing) method. Obviously, the grinding step may be omitted if there is no need to thin the wafer 72.

Next, referring to FIG. 8V, the field stop region 7 and the collector region 8 are formed in a surface layer portion of the second wafer main surface 74. In the step of forming the field stop region 7, an n-type impurity is introduced into the surface layer portion of the second wafer main surface 74 by an ion implantation method. In the step of forming the collector region 8, a p-type impurity is introduced into the surface layer portion of the second wafer main surface 74 by an ion implantation method. The collector region 8 is formed at the second wafer main surface 74 side with respect to the field stop region 7. An order of the step of forming the field stop region 7 and the step of forming the collector region 8 is arbitrary.

Next, referring to FIG. 8W, the second terminal electrode 57 is formed on the second wafer main surface 74. The step of forming the second terminal electrode 57 includes a step of forming the Ti film 58 as an ohmic electrode on the second wafer main surface 74. In this embodiment, the step of forming the second terminal electrode 57 includes a step of forming the Ni film 59, the Pd film 60, the Au film 61, and the Ag film 62 in that order from the Ti film 58 side. The Ti film 58, the Ni film 59, the Pd film 60, the Au film 61, and the Ag film 62 may be formed respectively by a vapor deposition method and/or a sputtering method.

Thereafter, the wafer 72 is cut along the dicing street 56 and a plurality of semiconductor devices 1 are cut out. By steps including above, the semiconductor device 1 is manufactured.

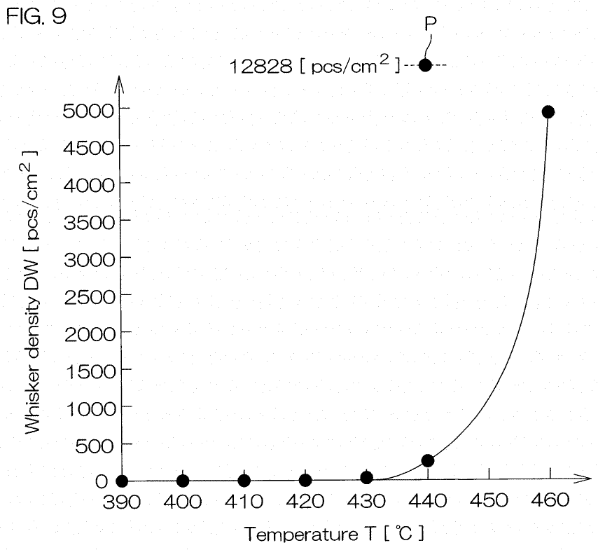

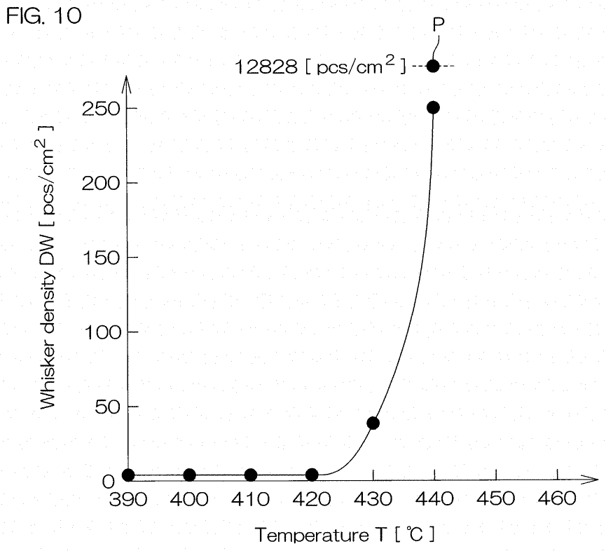

FIG. 9 is a graph of a relationship of the whisker density DW and the temperature T. FIG. 10 is a graph showing in enlarged manner the whisker density DW at a low temperature side shown in FIG. 9. In FIG. 9 and FIG. 10, the ordinate indicates the whisker density DW [whiskers/cm²] and the abscissa indicates the temperature T [° C.] of the high-temperature sputtering method during deposition of the Al-based metal 80.

In FIG. 9, the whisker density DW when the high-temperature sputtering method is performed in a range of the temperature T of not less than 390° C. to not more than 460° C. is shown. In FIG. 10, a range of the temperature T of not less than 390° C. to not more than 440° C. in the graph of FIG. 9 is enlarged. A plotted point P is shown in FIG. 9 and FIG. 10. The plotted point P indicates the whisker density DW (=12828 whiskers/cm²) when the Al-based metal film 44 is formed by the high-temperature sputtering method at 440° C. without forming the TiAl alloy film 43 (base Ti film 79).

Referring to FIG. 9 and FIG. 10, the whisker density DW increased when the temperature T increased. When the temperature T was not more than 460° C., the whisker density DW became not more than 5000 whiskers/cm². When the temperature T was not more than 450° C., the whisker density DW became not more than 1000 whiskers/cm². When the temperature T was not more than 445° C., the whisker density DW became not more than 500 whiskers/cm². When the temperature T was not more than 440° C., the whisker density DW became not more than 250 whiskers/cm². When the temperature T was not more than 430° C., the whisker density DW became not more than 50 whiskers/cm². When the temperature T was not more than 420° C., the whisker density DW became not more than 10 whiskers/cm².

Comparing with the plotted point P, the whisker density DW when the TiAl alloy film 43 (base Ti film 79) is introduced became less than the whisker density DW when the TiAl alloy film 43 (base Ti film 79) is not introduced. From this result, it was found that the forming of the whiskers 45 can be suppressed and the whisker density DW can be reduced by introducing the TiAl alloy film 43 (base Ti film 79).

When the TiAl alloy film 43 (base Ti film 79) is not present, the Al-based metal film 44 is film-formed with the TiN film 42 as a starting point. Consequently, the whiskers 45 are formed on the outer surface of the Al-based metal film 44 due to the TiN film 42. Thus, with the semiconductor device 1, the TiAl alloy film 43 (base Ti film 79) is formed on the TiN film 42. The Al-based metal film 44 can thereby be formed with the TiAl alloy film 43 as a starting point. Consequently, the Al-based metal film 44 can be suppressed from contacting the TiN film 42 and therefore, the forming of the whiskers 45 can be suppressed.

As a result of further examination by the present inventors, it was found that in a case where the base Ti film 79 is exposed to an oxygen atmosphere, although the whisker density DW can be reduced in comparison to the case where the TiAl alloy film 43 (base Ti film 79) is not present, there is a tendency of increase in whisker density DW in comparison to a case of not exposing to an oxygen atmosphere. That is, it was found that a risk of formation of the whiskers 45 increases when the Al-based metal film 44 is film-formed with a nitride of Ti (TiN), an oxide of Ti (TiO), or an oxynitride of Ti (TiNO) as a starting point.

It is therefore preferable to form the Al-based metal film 44 (TiAl alloy film 43) after forming the base Ti film 79 and without exposing the base Ti film 79 to an oxygen atmosphere. Also, it is preferable to form the Al-based metal film 44 (TiAl alloy film 43) after forming the base Ti film 79 and without exposing the base Ti film 79 to a nitrogen atmosphere.

Although specific illustration shall be omitted, when the temperature T of the high-temperature sputtering method exceeds 480° C., the whisker density DW decreases. Therefore, in terms of suppressing the whiskers 45, it is preferable to perform the high-temperature sputtering method at the temperature T exceeding 480° C. However, in this case, undesirable diffusion of the n-type impurity and the p-type impurity introduced into the wafer 72 is caused. Consequently, electrical characteristics of semiconductor regions such as the body region 9, the emitter regions 14, the contact regions 16, etc., vary and ohmic contacts between the first terminal electrode 30 and the semiconductor regions (especially the contact regions 16) degrade.

Thus, with the manufacturing method according to this embodiment, the high-temperature sputtering method is performed at the temperature T of not more than 480° C. (specifically, not less than 350° C. and not more than 480° C.). The diffusion of the impurities introduced into the wafer 72 can thereby be suppressed and degradation of ohmic properties of the first terminal electrode 30 can thus be suppressed. Also, although the whiskers 45 are formed easily if the temperature T is not more than 480° C., with the manufacturing method according to this embodiment, the forming of the whiskers 45 can be suppressed by the introduction of the TiAl alloy film 43 (base Ti film 79) as described above. The forming of the whiskers 45 can thus be suppressed while suppressing the degradation of the ohmic properties of the first terminal electrode 30. Also, since the forming of the whiskers 45 can be suppressed, film forming properties of various structures such as the resist mask 81, the top insulating film 50, etc., that are formed on the first terminal electrode 30 can be improved.

The temperature T according to the high-temperature sputtering method is preferably not less than 350° C. and not more than 460° C. The temperature T is especially preferably not less than 350° C. and not more than 440° C. A lower limit value of the temperature T may be not less than 390° C. The lower limit value of the temperature T is preferably not less than 400° C.

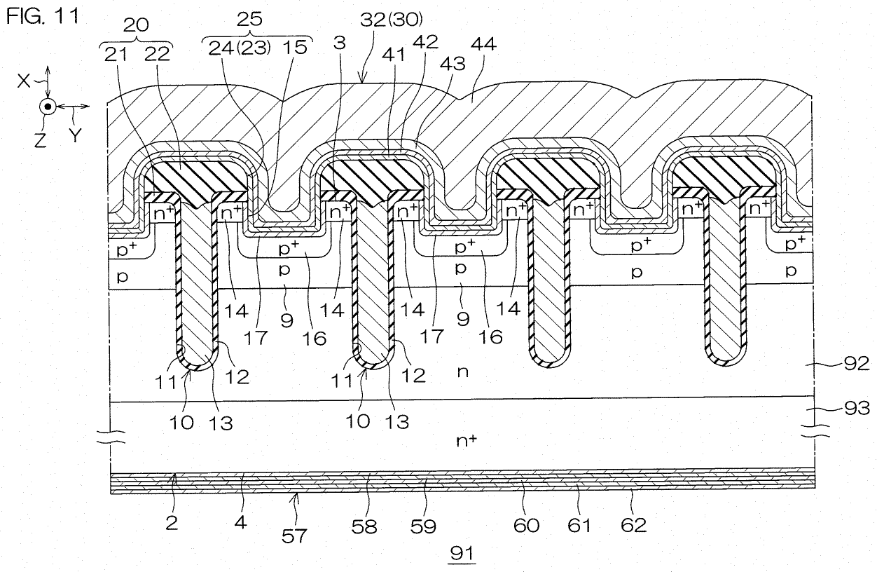

FIG. 11 is a sectional view, corresponding to FIG. 5, of a semiconductor device 91 according to a second preferred embodiment of the present invention. In the following, structures corresponding to structures described with respect to the semiconductor device 1 shall be provided with the same reference signs and description thereof shall be omitted.

Referring to FIG. 11, the semiconductor chip 2 according to the semiconductor device 91 includes a drift region 92 of the n-type and a drain region 93 of the n-type in place of the drift region 6, the field stop region 7, and the collector region 8. That is, the semiconductor device 91 is constituted of an electronic component (semiconductor switching device) that includes a MISFET (metal insulator semiconductor field effect transistor) in place of an IGBT as the functional device.

The drift region 92 corresponds to the drift region 6 described above and is exposed from portions of the first main surface 3 and the first to fourth side surfaces 5A to 5D. An n-type impurity concentration of the drift region 92 may be not less than 1×10¹⁵ cm⁻³ and not more than 1×10¹⁷ cm⁻³. In this embodiment, the drift region 92 is formed of an epitaxial layer (Si epitaxial layer) of the n-type. The drift region 92 may have a thickness of not less than 5 μm and not more than 100 μm.

The drain region 93 is formed in a region at the second main surface 4 side with respect to the drift region 92. The drain region 93 is exposed from portions of the second main surface 4 and the first to fourth side surfaces 5A to 5D and is electrically connected to the drift region 92. The drain region 93 has an n-type impurity concentration that exceeds the n-type impurity concentration of the drift region 92.

The n-type impurity concentration of the drain region 93 may be not less than 1×10¹⁸ cm⁻³ and not more than 1×10²¹ cm⁻³. In this embodiment, the drain region 93 is formed of a semiconductor substrate (Si substrate) of the n-type. A thickness of the drain region 93 may be not less than 10 μm and not more than 450 μm. The thickness of the drain region 93 is preferably not less than 50 μm and not more than 150 μm.

In the semiconductor device 91, the emitter regions 14 according to the semiconductor device 1 function as source regions of the MISFET. The semiconductor device 91 is manufactured by preparing a wafer 72 that includes the drift region 92 and the drain region 93 (that is, an epitaxial wafer that includes a semiconductor wafer and an epitaxial layer) in the step of FIG. 8A. The same effects as the effects described for the semiconductor device 1 are exhibited even by the semiconductor device 91 described above.

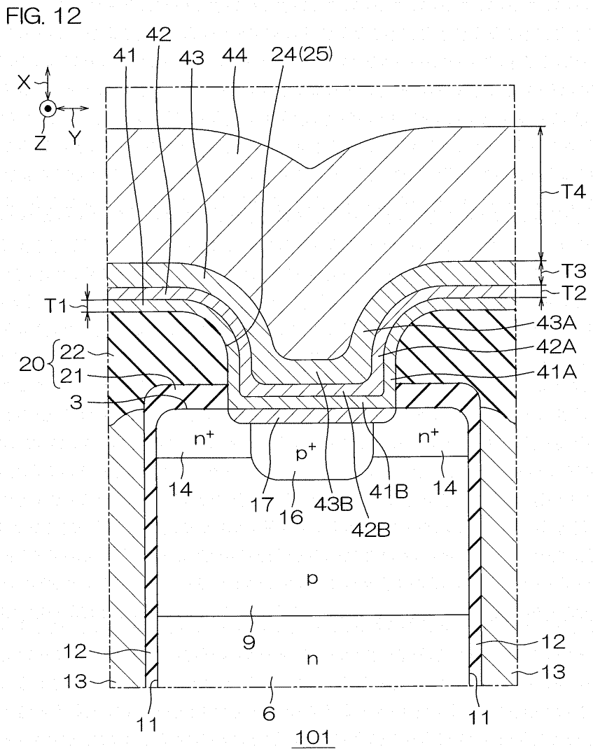

FIG. 12 is a sectional view, corresponding to FIG. 5, of a semiconductor device 101 according to a third preferred embodiment of the present invention. In the following, structures corresponding to structures described with respect to the semiconductor device 1 shall be provided with the same reference signs and description thereof shall be omitted.

Referring to FIG. 12, the semiconductor device 101 does not have the contact holes 15. Each Ti silicide layer 17 according to the semiconductor device 101 is formed in a region of the first main surface 3 between two neighboring trench structures 10. the Ti silicide layers 17 are formed at intervals from the plurality of trench structures 10. Specifically, each Ti silicide layer 17 is formed such as to cross a surface layer portion of a contact region 16 and extend between surface layer portions of two neighboring emitter regions 14. The Ti silicide layer 17 forms ohmic contacts with the emitter regions 14 and the contact region 16.

The emitter penetrating holes 24 according to the semiconductor device 101 are formed as the emitter openings 25 and expose the emitter regions 14 and the contact regions 16. Specifically, the emitter penetrating holes 24 expose the Ti silicide layers 17.

The first terminal electrode 30 has a laminated structure that includes the Ti film 41, the TiN film 42, the TiAl alloy film 43, and the Al-based metal film 44 and enters into the plurality of emitter openings 25 from above the main surface insulating film 20. In the following, points by which the Ti film 41, the TiN film 42, the TiAl alloy film 43, and the Al-based metal film 44 differ from those of the first preferred embodiment shall be described.

The Ti film 41 is formed on the main surface insulating film 20. The Ti film 41 enters into each emitter opening 25 from above the main surface insulating film 20 and is electrically connected to the semiconductor chip 2 inside the emitter opening 25. As in the first preferred embodiment, the Ti film 41 includes the first side wall portion 41A and the first bottom wall portion 41B that demarcate a recess space inside the emitter opening 25.

The first side wall portion 41A covers the side wall of the emitter opening 25 as a film. The first bottom wall portion 41B covers the bottom wall of the emitter opening 25 as a film. The first surface and the second surface of the first bottom wall portion 41B are positioned at the semiconductor chip 2 side with respect to the main surface of the main surface insulating film 20 and covers the Ti silicide layer 17. The Ti film 41 is electrically connected to the Ti silicide layer 17 at the first bottom wall portion 41B.

The TiN film 42 is formed as a film on the Ti film 41. The TiN film 42 enters into the emitter opening 25 from above the Ti film 41 and is electrically connected to the Ti film 41 inside and outside the emitter opening 25. As in the first preferred embodiment, the TiN film 42 includes the second side wall portion 42A and the second bottom wall portion 42B that demarcate a recess space inside the emitter opening 25.

The second side wall portion 42A covers, as a film, the side wall of the emitter opening 25 across the first side wall portion 41A of the Ti film 41. The second bottom wall portion 42B covers, as a film, the bottom wall of the emitter opening 25 across the first bottom wall portion 41B of the Ti film 41. The third surface and the fourth surface of the second bottom wall portion 42B are positioned at the bottom wall side of the emitter opening 25 with respect to the main surface of the main surface insulating film 20. The TiN film 42 is electrically connected to the Ti silicide layer 17 at the second bottom wall portion 42B and via the Ti film 41.

The TiAl alloy film 43 is formed as a film on the TiN film 42. The TiAl alloy film 43 enters into the emitter opening 25 from above the TiN film 42 and is electrically connected to the TiN film 42 inside and outside the emitter opening 25. As in the first preferred embodiment, the TiAl alloy film 43 includes the third side wall portion 43A and the third bottom wall portion 43B that demarcate a recess space inside the emitter opening 25.

The third side wall portion 43A covers, as a film, the side wall of the emitter opening 25 across the first side wall portion 41A of the Ti film 41 and the second side wall portion 42A of the TiN film 42. The third bottom wall portion 43B covers, as a film, the bottom wall of the emitter opening 25 across the first bottom wall portion 41B of the Ti film 41 and the second bottom wall portion 42B of the TiN film 42. The fifth surface and the sixth surface of the third bottom wall portion 43B are positioned at the TiN film 42 side with respect to the main surface of the main surface insulating film 20. The TiAl alloy film 43 is electrically connected to the Ti silicide layer 17 at the third bottom wall portion 43B and via the TiN film 42 and the Ti film 41.

The Al-based metal film 44 is formed as a film on the TiAl alloy film 43. The Al-based metal film 44 enters into the emitter opening 25 from above the TiN film 42 and is electrically connected to the TiAl alloy film 43 inside and outside the emitter opening 25. As in the first preferred embodiment, the Al-based metal film 44 refills the recess space demarcated by the TiAl alloy film 43 inside the emitter opening 25. That is, the portion of the Al-based metal film 44 that is positioned inside the emitter opening 25 is formed as an anchor portion engaged with the recess space demarcated by the TiAl alloy film 43.

The seventh surface of the Al-based metal film 44 includes a portion positioned inside the emitter opening 25 and a portion positioned outside the emitter opening 25. On the other hand, the entirety of the eighth surface of the TiAl alloy film 43 is positioned outside the emitter opening 25. A portion of the eighth surface of the TiAl alloy film 43 that faces the emitter opening 25 is depressed toward the semiconductor chip 2 side. The Al-based metal film 44 is electrically connected to the Ti silicide layer 17 via the TiAl alloy film 43, the TiN film 42, and the Ti film 41.

As described above, a portion of the emitter terminal 32 that is positioned inside the emitter opening 25 is formed of a laminated structure that includes the Ti film 41, the TiN film 42, the TiAl alloy film 43, and the Al-based metal film 44. Although a specific description shall be omitted, a portion of the gate terminal 31 that is positioned inside a gate opening (not shown) has the same form as the portion of the emitter terminal 32 positioned inside the emitter opening 25. That is, like the emitter terminal 32, a portion of the gate terminal 31 positioned inside a penetrating hole 23 (that is, a gate opening (not shown)) is formed of the laminated structure that includes the Ti film 41, the TiN film 42, the TiAl alloy film 43, and the Al-based metal film 44.

The semiconductor device 101 is manufactured by omitting the step of forming the contact holes 15 in the step of FIG. 8I. The same effects as the effects described for the semiconductor device 1 are exhibited even by the semiconductor device 101 described above. The structure according to the semiconductor device 101 can also be applied to the semiconductor device 91 according to the second preferred embodiment.

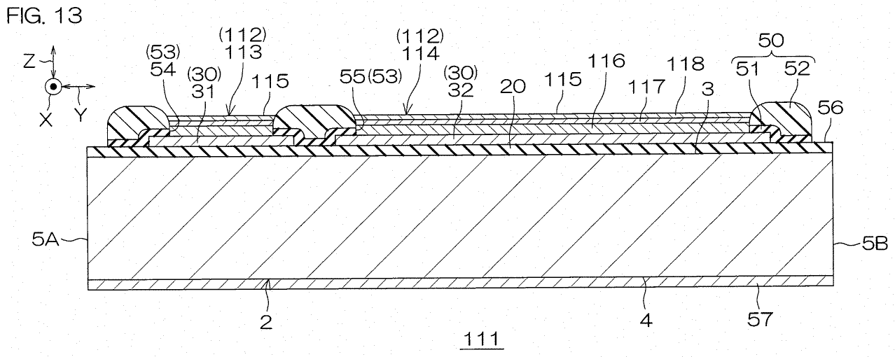

FIG. 13 is a sectional view, corresponding to FIG. 2, of a semiconductor device 111 according to a third preferred embodiment of the present invention. In the following, structures corresponding to structures described with respect to the semiconductor device 1 shall be provided with the same reference signs and description thereof shall be omitted.

The semiconductor device 111 further includes a pad electrode 112 formed on the first terminal electrode 30. Specifically, the pad electrode 112 includes a gate pad electrode 113 and an emitter pad electrode 114. The gate pad electrode 113 is formed on the gate terminal 31 and is electrically connected to the gate terminal 31. The emitter pad electrode 114 is formed on the emitter terminal 32 and is electrically connected to the emitter terminal 32. The pad electrode 112 has a terminal surface 115 that is externally connected to lead wires (for example, bonding wires).

In this embodiment, the terminal surface 115 is positioned at the first terminal electrode 30 side with respect to a main surface of the top insulating film 50 (organic insulating film 52). The terminal surface 115 may be projected further upward than the main surface of the top insulating film 50 (organic insulating film 52). In this case, the terminal surface 115 may have an overlap portion that covers the main surface of the top insulating film 50 (organic insulating film 52).

The pad electrode 112 includes a metal material differing from that of the first terminal electrode 30. In this embodiment, the pad electrode 112 has a laminated structure that includes an Ni film 116, a Pd film 117, and an Au film 118 that are laminated in that order from the first terminal electrode 30 side. The pad electrode 112 suffices to include at least one among the Ni film 116, the Pd film 117, and the Au film 118. The pad electrode 112 may have a single layer structure constituted of the Ni film 116, the Pd film 117, or the Au film 118.

The pad electrode 112 may have a laminated structure in which at least two among the Ni film 116, the Pd film 117, and the Au film 118 are laminated in any order. The pad electrode 112 preferably has the terminal surface 115 that is formed of the Au film 118. The pad electrode 112 preferably has a laminated structure that at least includes the Ni film 116 and the Au film 118 that are laminated in that order from the first terminal electrode 30 side.

A thickness of the Ni film 116 may be not less than 0.1 μm and not more than 10 μm. A thickness of the Pd film 117 may be not less than 0.1 μm and not more than 10 μm. A thickness of the Au film 118 may be not less than 0.01 μm and not more than 3 μm. The thickness of the Au film 118 is preferably less than the thickness of the Ni film 116. The thickness of the Au film 118 is preferably less than the thickness of the Pd film 117.

The semiconductor device 111 is manufactured by adding a step of forming the pad electrode 112 on the first terminal electrode 30 after the plurality of pad openings 53 have been formed in the step shown in FIG. 8T. The step of forming the pad electrode 112 includes a step of forming the Ni film 116, the Pd film 117, and the Au film 118 in that order from the first terminal electrode 30 side. The Ni film 116, the Pd film 117, and the Au film 118 may be formed respectively by an electroless plating method.

The same effects as the effects described for the semiconductor device 1 are exhibited even by the semiconductor device 111 described above. The structure according to the semiconductor device 111 can also be applied to the semiconductor device 91 according to the second preferred embodiment and the semiconductor device 101 according to the third preferred embodiment.

The present invention can be implemented in other embodiments.

In each of the preferred embodiments described above, a structure with which the conductivity types of the respective semiconductor portions are inverted may be adopted. That is, a portion of the p-type may be formed to be of the n-type and a portion of the n-type may be formed to be of the p-type.

With the respective preferred embodiments described above, examples of adopting an IGBT and a MISFET as the functional devices were described. However, the electrode structure that includes the Ti film 41, the TiN film 42, the TiAl alloy film 43, and the Al-based metal film 44 can be applied to a diode, a resistor, a capacitor, a coil, and other various functional devices besides an IGBT and a MISFET.

Examples of features extracted from this description and the drawings are indicated below. In the following, a semiconductor device with which whiskers are suppressed and a method for manufacturing the same and an electronic component and a method for manufacturing the same are provided. Although in the following, alphanumeric characters inside parenthesis represent corresponding constituents in the preferred embodiments described above, this is not meant to restrict the scopes of the respective items to the preferred embodiments.

[A1] A semiconductor device (1, 91, 101, 111) comprising, a chip (2) and an electrode (30) that has a laminated structure including a Ti film (41), a TiN film (42), a TiAl alloy film (43) and an Al-based metal film (44) that are laminated in that order from the chip (2) side.

[A2] The semiconductor device (1, 91, 101, 111) according to A1, wherein the electrode (30) has a whisker density (DW) of not more than 5000 whiskers/cm² at a surface of the Al-based metal film (44).

[A3] The semiconductor device (1, 91, 101, 111) according to A2, wherein the whisker density (DW) is not more than 500 whiskers/cm².

[A4] The semiconductor device (1, 91, 101, 111) according to any one of A1 to A3, further comprising, an insulating film (20) that covers the chip (2) and has a penetrating hole (23) exposing the chip (2), and wherein the electrode (30) enters into the penetrating hole (23) from above the insulating film (20) and is electrically connected to the chip (2) inside the penetrating hole (23).

[A5] The semiconductor device (1, 91, 101, 111) according to A4, wherein the laminated structure including the Ti film (41), the TiN film (42), the TiAl alloy film (43) and the Al-based metal film (44) is positioned inside the penetrating hole (23).

[A6] The semiconductor device (1, 91, 101, 111) according to any one of A1 to A5, wherein the TiAl alloy film (43) is thicker than the TiN film (42) and the Al-based metal film (44) is thicker than the TiAl alloy film (43).

[A7] The semiconductor device (1, 91, 101, 111) according to any one of A1 to A, wherein the Al-based metal film (44) includes at least one among a pure Al film, an AlSi alloy film, an AlCu alloy film and an AlSiCu alloy film.

[A8] The semiconductor device (1, 91, 101, 111) according to any one of A1 to A7, further comprising, a semiconductor region (9, 14, 16) that is formed in a surface layer portion of the chip (2), and wherein the electrode (30) is electrically connected to the semiconductor region (9, 14, 16).

[A9] The semiconductor device (1, 91, 101, 111) according to any one of A1 to A8, further comprising, a Ti silicide layer (17) that is formed in a surface layer portion of the chip (2), and wherein the electrode (30) is electrically connected to the Ti silicide layer (17).

[A10] The semiconductor device (1, 91, 101, 111) according to any one of A1 to A9, wherein the chip (2) is constituted of an Si chip or an SiC chip.

[A11] The semiconductor device (1, 91, 101, 111) according to any one of A1 to A10, further comprising, a top insulating film (50) that covers the electrode (30) and has a pad opening (53) that exposes a portion of the electrode (30).

[A12] A method for manufacturing a semiconductor device (1, 91, 101, 111) comprising, a step of forming a Ti film (41) on a wafer (72), a step of forming a TiN film (42) on the Ti film (41), a step of forming a base Ti film (79) on the TiN film (42), a step of forming a TiAl alloy film (43) by alloying an Al-based metal (80) with the base Ti film (79) by depositing the Al-based metal on the base Ti film (79) by a high-temperature sputtering method, and a step of forming an Al-based metal film (44) by continuing to deposit the Al-based metal (80) on the TiAl alloy film (43) by the high-temperature sputtering method.

[A13] The method for manufacturing the semiconductor device (1, 91, 101, 111) according to A12, wherein the step of forming the TiAl alloy film (43) includes a step of depositing the Al-based metal (80) on the base Ti film (79) without exposing the base Ti film (79) to an oxygen atmosphere.

[A14] The method for manufacturing the semiconductor device (1, 91, 101, 111) according to A12 or A13, wherein the high-temperature sputtering method is performed at a temperature (T) of not less than 350° C. and not more than 480° C.

[A15] The method for manufacturing the semiconductor device (1, 91, 101, 111) according to A14, wherein the temperature (T) is not more than 460° C.

[A16] The method for manufacturing the semiconductor device (1, 91, 101, 111) according to any one of A12 to A15, wherein the TiAl alloy film (43) that is thicker than the TiN film (42) is formed in the step of forming the TiAl alloy film (43), and the Al-based metal film (44) that is thicker than the TiAl alloy film (43) is formed in the step of forming the Al-based metal film (44).

[A17] The method for manufacturing the semiconductor device (1, 91, 101, 111) according to any one of A12 to A16, further comprising, a step of forming an insulating film (20) that covers the wafer (72) and has a penetrating hole (23) partially exposing the wafer (72) before the step of forming the Ti film (41), and wherein the Ti film (41) enters into the penetrating hole (23) from above the insulating film (20) and is connected to the wafer (72) inside the penetrating hole (23).

[A18] The method for manufacturing the semiconductor device (1, 91, 101, 111) according to any one of A12 to A17, further comprising, a step of forming a Ti silicide at a connection portion of the Ti film (41) and the wafer (72) by an annealing treatment method before the step of forming the TiN film (42).

[A19] The method for manufacturing the semiconductor device (1, 91, 101, 111) according to any one of A12 to A18, wherein the Al-based metal (80) includes at least one among pure A1, an AlSi alloy, an AlCu alloy and an AlSiCu alloy.

[B1] An electronic component (1, 91, 101, 111) comprising, an insulator (20), and an electrode (30) that has a laminated structure including a Ti film (41), a TiN film (42), a TiAl alloy film (43) and an Al-based metal film (44) that are laminated in that order from the insulator (20) side. By this structure, an electronic component with which whiskers are suppressed can be provided.

[B2] The electronic component (1, 91, 101, 111) according to B1, wherein the electrode (30) has a whisker density (DW) of not more than 5000 whiskers/cm² at a surface of the Al-based metal film (44).

[B3] The electronic component (1, 91, 101, 111) according to B2, wherein the whisker density (DW) is not more than 500 whiskers/cm².

[B4] The electronic component (1, 91, 101, 111) according to any one of B1 to B3, further comprising, a functional device, and wherein the insulator (20) covers the functional device.

[B5] The electronic component (1, 91, 101, 111) according to any one of B1 to B4, wherein the insulator (20) has a penetrating hole (23) that exposes a portion of the functional device and the electrode (30) enters into the penetrating hole (23) from above the insulator (20) and is electrically connected to a portion of the functional device inside the penetrating hole (23).

[B6] The electronic component (1, 91, 101, 111) according to B5, wherein the laminated structure including the Ti film (41), the TiN film (42), the TiAl alloy film (43) and the Al-based metal film (44) is positioned inside the penetrating hole (23).

[B7] The electronic component (1, 91, 101, 111) according to any one of B1 to B6, wherein the TiAl alloy film (43) is thicker than the TiN film (42), and the Al-based metal film (44) is thicker than the TiAl alloy film (43).

[B8] The electronic component (1, 91, 101, 111) according to any one of B1 to B7, wherein the Al-based metal film (44) includes at least one among a pure Al film, an AlSi alloy film, an AlCu alloy film and an AlSiCu alloy film.

[B9] A method for manufacturing an electronic component (1, 91, 101, 111) comprising, a step of forming a TiN film (42) on a Ti film (41), a step of forming a base Ti film (79) on the TiN film (42), a step of forming a TiAl alloy film (43) by alloying an Al-based metal (80) with the base Ti film (79) by depositing the Al-based metal on the base Ti film (79) by a high-temperature sputtering method, and a step of forming an Al-based metal film (44) by continuing to deposit the Al-based metal (80) on the TiAl alloy film (43) by the high-temperature sputtering method. By this manufacturing method, an electronic component with which whiskers are suppressed can be provided.

[B10] The method for manufacturing the electronic component (1, 91, 101, 111) according to B9, further comprising, a step of forming the Ti film (41) on an insulator (20) before the step of forming the TiN film (42).

[B11] The method for manufacturing the electronic component (1, 91, 101, 111) according to B9 or B10, wherein the step of forming the TiAl alloy film (43) includes a step of depositing the Al-based metal (80) on the base Ti film (79) without exposing the base Ti film (79) to an oxygen atmosphere.

[B12] The method for manufacturing the electronic component (1, 91, 101, 111) according to any one of B9 to B11, wherein the high-temperature sputtering method is performed at a temperature (T) of not less than 350° C. and not more than 480° C.

[B13] The method for manufacturing the electronic component (1, 91, 101, 111) according to B12, wherein the temperature is not more than 460° C.

[B14] The method for manufacturing the electronic component (1, 91, 101, 111) according to any one of B9 to B13, wherein the TiAl alloy film (43) that is thicker than the TiN film (42) is formed in the step of forming the TiAl alloy film (43), and the Al-based metal film (44) that is thicker than the TiAl alloy film (43) is formed in the step of forming the Al-based metal film (44).

[B15] The method for manufacturing the electronic component (1, 91, 101, 111) according to any one of B9 to B14, wherein the Al-based metal (80) includes at least one among pure A1, an AlSi alloy, an AlCu alloy and an AlSiCu alloy.

While preferred embodiments of the present invention have been described in detail, these are merely specific examples used to clarify the technical contents of the present invention and the present invention should not be interpreted as being limited to these specific examples and the scope of the present invention is to be limited only by the appended claims.

### REFERENCE SIGNS LIST

1 semiconductor device
2 semiconductor chip
17 Ti silicide film
20 main surface insulating film
23 penetrating hole
30 first terminal electrode
41 Ti film
42 TiN film
43 TiAl alloy film
44 Al-based metal film
50 top insulating film
53 pad opening
72 wafer
79 base Ti film
80 Al-based metal
91 semiconductor device
101 semiconductor device
111 semiconductor device
DW whisker density

1. A semiconductor device comprising:
a chip; and
an electrode that has a laminated structure including a Ti film, a TiN film, a TiAl alloy film and an Al-based metal film that are laminated in that order from the chip side.

2. The semiconductor device according to claim 1, wherein the electrode has a whisker density of not more than 5000 whiskers/cm² at a surface of the Al-based metal film.

3. The semiconductor device according to claim 2, wherein the whisker density is not more than 500 whiskers/cm².

4. The semiconductor device according to claim 1, wherein the TiAl alloy film is thicker than the TiN film, and
the Al-based metal film is thicker than the TiAl alloy film.

5. The semiconductor device according to claim 1, further comprising:
an insulating film that covers the chip and has a penetrating hole exposing the chip, and
wherein the electrode enters into the penetrating hole from above the insulating film and is electrically connected to the chip inside the penetrating hole.

6. The semiconductor device according to claim 5, wherein the laminated structure including the Ti film, the TiN film, the TiAl alloy film and the Al-based metal film is positioned inside the penetrating hole.

7. The semiconductor device according to claim 1, further comprising:
a top insulating film that covers the electrode and has a pad opening that exposes a portion of the electrode.

8. The semiconductor device according to claim 1, further comprising:
a semiconductor region that is formed in a surface layer portion of the chip; and
wherein the electrode is electrically connected to the semiconductor region.

9. The semiconductor device according to claim 1, further comprising:
a Ti silicide layer that is formed in a surface layer portion of the chip; and
wherein the electrode is electrically connected to the Ti silicide layer.

10. The semiconductor device according to claim 1, wherein the Al-based metal film includes at least one among a pure Al film, an AlSi alloy film, an AlCu alloy film and an AlSiCu alloy film.

11. The semiconductor device according to claim 1, wherein the chip is constituted of an Si chip or an SiC chip.

12. A method for manufacturing a semiconductor device comprising:
a step of forming a Ti film on a wafer;
a step of forming a TiN film on the Ti film;
a step of forming a base Ti film on the TiN film;
a step of forming a TiAl alloy film by alloying an Al-based metal with the base Ti film by depositing the Al-based metal on the base Ti film by a high-temperature sputtering method; and
a step of forming an Al-based metal film by continuing to deposit the Al-based metal on the TiAl alloy film by the high-temperature sputtering method.

13. The method for manufacturing the semiconductor device according to claim 12, wherein the step of forming the TiAl alloy film includes a step of depositing the Al-based metal on the base Ti film without exposing the base Ti film to an oxygen atmosphere.

14. The method for manufacturing the semiconductor device according to claim 12, wherein the high-temperature sputtering method is performed at a temperature of not less than 350° C. and not more than 480° C.

15. The method for manufacturing the semiconductor device according to claim 14, wherein the temperature is not more than 460° C.

16. The method for manufacturing the semiconductor device according to claim 12, wherein the TiAl alloy film that is thicker than the TiN film is formed in the step of forming the TiAl alloy film, and
the Al-based metal film that is thicker than the TiAl alloy film is formed in the step of forming the Al-based metal film.

17. The method for manufacturing the semiconductor device according to claim 12, further comprising:
a step of forming an insulating film that covers the wafer and has a penetrating hole partially exposing the wafer before the step of forming the Ti film, and
wherein the Ti film enters into the penetrating hole from above the insulating film and is connected to the wafer inside the penetrating hole.

18. The method for manufacturing the semiconductor device according to claim 12, further comprising:
a step of forming a Ti silicide at a connection portion of the Ti film and the wafer by an annealing treatment method before the step of forming the TiN film.

19. The method for manufacturing the semiconductor device according to claim 12, wherein the Al-based metal includes at least one among pure Al, an AlSi alloy, an AlCu alloy and an AlSiCu alloy.
